(19) United States
(12) Patent Application Publication
(10) Pub. No.: US 2014/0374677 A1
(43) Pub. Date: Dec. 25, 2014

(54) COLORED COMPOSITION, COLORED PHOTOSENSITIVE COMPOSITION, COLOR FILTER AND LIQUID CRYSTAL DISPLAY DEVICE EQUIPPED WITH SAME, ORGANIC EL DISPLAY DEVICE, AND SOLID-STATE IMAGE SENSOR

(71) Applicant: FUJIFILM CORPORATION, Tokyo (JP)

(72) Inventors: Shuichiro OSADA, Fujinomiya-shi (JP); Kazumasa MOROZUMI, Fujinomiya-shi (JP); Yuuichi FUKUSHIGE, Fujinomiya-shi (JP)

(73) Assignee: FUJIFILM CORPORATION, Tokyo (JP)

(21) Appl. No.: 14/478,846

(22) Filed: Sep. 5, 2014

Related U.S. Application Data
(63) Continuation of application No. PCT/JP2013/056365, filed on Mar. 7, 2013.

(30) Foreign Application Priority Data
Mar. 7, 2012 (JP) 2012-051017

(51) Int. Cl. G02B 5/20; G03F 7/031; G03C 1/735

(52) U.S. Cl. CPC G02B 5/20; G03C 1/735; G03F 7/031
USPC 252/586; 106/411; 106/413; 430/285.1

(57) ABSTRACT

A colored composition including: (A) a phthalocyanine compound having a particular structure, (B) a yellow coloring material, and (C) a solvent.

### CROSS-REFERENCE TO RELATED APPLICATIONS

This application is a continuation application of International Application No. PCT/JP2013/056365, filed Mar. 7, 2013, the disclosure of which is incorporated herein by reference in its entirety. Further, this application claims priority from Japanese Patent Application No. 2012-051017, filed Mar. 7, 2012, the disclosure of which is incorporated herein by reference in its entirety.

### TECHNICAL FIELD

The present invention relates to a colored composition for a color filter and a colored photosensitive composition for a color filter, which are suitable for the formation of colored images included in color filters that are used in liquid crystal display devices (LCD), organic EL display devices (OLED), solid-state image sensors (CCD, CMOS and the like) and the like, and also relates to a color filter, a liquid crystal display device, an organic EL display device, and a solid-state image sensor, in which the composition is used.

### BACKGROUND ART

Regarding the method of producing a color filter that is used in liquid crystal display devices, organic EL display devices, solid-state image sensors and the like, there are known a dyeing method, a printing method, an electrodeposition method, and a pigment dispersion method.

Among these, a pigment dispersion method is a method of producing color filters according to a photolithographic method using colored photosensitive compositions obtained by dispersing pigments in various photosensitive compositions, and the method is advantageous in that since pigments are used, the products are stable to light, heat and the like. Furthermore, since patterning is achieved according to a photolithographic method, the pigment dispersion method has high positional accuracy, and has been widely used as a suitable method of producing a color filter for large-screen, high-precision color displays.

When a color filter is produced by a pigment dispersion method, a colored photosensitive composition is applied on a glass substrate using a spin coater, a roll coater or the like and dried to form a coating film, and colored pixels are formed by patternwise exposing and developing the coating film. When this operation is repeatedly carried out for each color, a color filter can be obtained.

Use of a dye as a colorant is considered useful from the viewpoint that, due to the color purity of the dye itself or the vividness of the hue, the hue or luminance of displayed images on the occasion of image display can be improved. Thus, a technology of using dyes instead of pigments has been proposed (see, for example, Japanese Patent Application Laid-Open (JP-A) No. H06-75375). Also, methods of using a color filter in which a dye and a pigment are employed in combination are described in the specifications of JP-A No. H05-119211, JP-A No. 2008-15530, and US Patent Application Publication No. 2008/0171271 A1.

### SUMMARY OF INVENTION

### Technical Problem

The methods using dyes as described above are intended to improve heat resistance and light resistance, or to enhance contrast by reducing pigment particles; however, the methods provide an improvement in the spectroscopic characteristics as for a color filter only at an insufficient level.

Particularly, the decrease in luminance occurring when color reproducibility is enhanced, which has been hitherto a problem, is not much improved according to the methods described above, and there has been a demand for the development of a color filter which can provide a sufficient color reproduction range when the color filter is applied to a display device, and causes a less decrease in luminance.

Therefore, an object of the invention is to provide a color filter which exhibits excellent color reproducibility when applied to an image display device such as an LCD or an organic EL of a color filter system, and to provide a colored composition and a colored photosensitive composition, each having heat resistance and high luminance. Another object of the invention is to provide, when a color filter obtained using the colored photosensitive composition is produced, a color filter exhibiting high luminance, and to provide a liquid crystal display device, and an organic EL display device, which are capable of displaying images with high luminance, and a solid-state image sensor.

### Solution to Problem

The above objects of the invention are achieved by the following means.

<1> A colored composition, comprising: (A) a compound represented by the following Formula (1); (B) a yellow coloring material; and (C) a solvent:

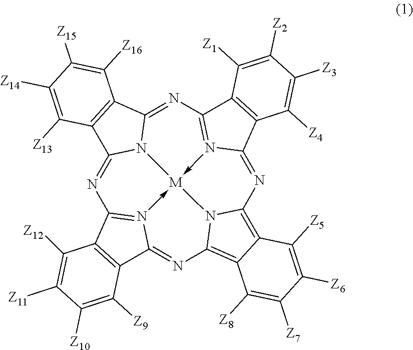

wherein, in Formula (1), each of Z₁ to Z₁₆ independently represents a hydrogen atom, a halogen atom, a group represented by the following Chemical Formula (2), a group represented by the following Chemical Formula (3), or a group represented by the following Chemical Formula (2′); from one to eight of Z₁ to Z₁₆ each independently represent a group represented by the following Chemical Formula (2) or a group represented by the following Chemical Formula (2′); at least one of the from one to eight of Z₁ to Z₁₆ represents a group represented by the following Chemical Formula (2); and M represents two hydrogen atoms, a metal atom, a metal oxide, or a metal halide:

—X-A₁ Chemical Formula (2):

wherein, in Chemical Formula (2), X represents an oxygen atom or a sulfur atom; A₁ represents a phenyl group, a phenyl group having one to five substituents R, or a naphthyl group having one to seven substituents R; each of the substituents R independently represents a nitro group, COOR₁, OR₂, a halogen atom, an aryl group, a cyano group, or an alkyl group that has 1 to 8 carbon atoms and that may be substituted with a halogen atom; R₁ represents an alkyl group having 1 to 8 carbon atoms; the alkyl group having 1 to 8 carbon atoms represented by R₁ may be substituted with an alkyloxy group having 1 to 8 carbon atoms, a halogen atom, or an aryl group; and R₂ represents an alkyl group having 1 to 8 carbon atoms:

R₃—OₙR₄ Chemical Formula (3):

wherein, in Chemical Formula (3), R₃ represents an alkylene group having 1 to 3 carbon atoms; R₄ represents an alkyl group having 1 to 8 carbon atoms; and n represents an integer from 1 to 4:

—OR′—OₗR″ Chemical Formula (2′):

wherein, in Chemical Formula (2′), R′ represents an alkylene group having 1 to 3 carbon atoms; R″ represents an alkyl group having 1 to 8 carbon atoms; and 1 represents an integer from 0 to 4.

<2> The colored composition according to <1>, wherein, in Formula (1), M represents at least one selected from the group consisting of a copper atom, a zinc atom, a cobalt atom, a nickel atom, an iron atom, vanadyl, titanyl, indium chloride, and tin(II) chloride.

<3> The colored composition according to <1> or <2>, wherein, in Formula (1), from one to eight of Z₁ to Z₁₆ each independently represent a group represented by Chemical Formula (2) or a group represented by Chemical Formula (2′), and at least one of the from one to eight of Z₁ to Z₁₆ represents a group represented by Chemical Formula (2), while the remainder of Z₁ to Z₁₆ each independently represent a hydrogen atom or a chlorine atom.

<4> The colored composition according to any one of <1> to <3>, wherein, in Formula (1), any one or more of Z₁ to Z₁₆ represents a fluorine atom, a chlorine atom, a bromine atom, or an iodine atom.

<5> The colored composition according to any one of <1> to <4>, wherein, in Chemical Formula (2), X represents an oxygen atom.

<6> The colored composition according to any one of <1> to <5>, wherein (B) the yellow coloring material includes at least one selected from the group consisting of Pigment Yellow 138, Pigment Yellow 150, a compound represented by the following Formula (6), and a compound represented by the following Formula (7):

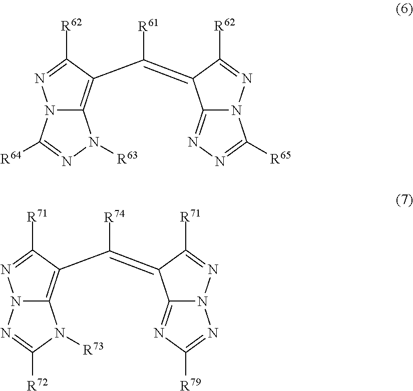

wherein, in Formula (6) and Formula (7), each of R⁶¹ to R⁶⁵, R⁷¹ to R⁷⁴, and R⁷⁹ independently represents a hydrogen atom, an alkyl group, an alkoxy group, an alkoxycarbonyl group, a carbamoyl group, a sulfamoyl group, a cyano group, an aryl group, or a heteroaryl group.

<7> The colored composition according to any one of <1> to <6>, further comprising at least one green pigment selected from the group consisting of Pigment Green 7, Pigment Green 36, and Pigment Green 58.

<8> A colored photosensitive composition, comprising: the colored composition according to any one of <1> to <7>; (D) a polymerizable compound; (E) a photopolymerization initiator; and (F) an alkali-soluble binder.

<9> The colored photosensitive composition according to <8>, wherein (E) the photopolymerization initiator includes at least one selected from the group consisting of a compound containing an oxime ester, and a hexaarylbisimidazole compound.

<10> The colored photosensitive composition according to <8> or <9>, wherein (F) the alkali-soluble binder has an ethylenically unsaturated group as a substituent.

<11> The colored composition according to any one of <1> to <10>, wherein (C) the solvent is an organic acid ester.

<12> A color filter, comprising a colored layer formed using the colored photosensitive composition according to any one of <8> to <11>.

<13> A liquid crystal display device, comprising the color filter according to <12>.

<14> An organic EL display device, comprising the color filter according to <12>. <15> A solid-state image sensor, comprising the color filter according to <12>.

### Advantageous Effects of Invention

According to the invention, a colored composition and a colored photosensitive composition, each having heat resistance and high luminance, can be provided. Furthermore, when a color filter obtained using the colored photosensitive composition is produced, a liquid crystal display device, and an organic EL display device, which are capable of displaying images with high luminance, and a solid-state image sensor can be provided.

### DESCRIPTION OF EMBODIMENTS

Hereinafter, the colored composition and colored photosensitive composition of the invention will be described in detail. In the present specification, “- (to)” represents the range of the lower limit value or more and the upper limit value or less. Furthermore, in regard to the description of a group in the present specification, a description without the indication of substitution or unsubstitution means to encompass both a group that does not have a substituent, and a group that has a substituent.

The colored composition of the invention is characterized by including a compound represented by Formula (1), a yellow coloring material, and a solvent, and the colored photosensitive composition is characterized by including the colored composition, a polymerizable compound, a polymerization initiator, and a resin. The components included in the colored composition and the colored photosensitive composition of the invention will be explained below.

The colored composition of the invention is characterized by including a compound represented by Formula (1).

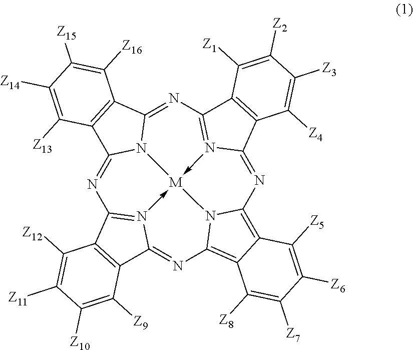

In the above Formula (1), each of Z₁ to Z₁₆ independently represents a hydrogen atom, a halogen atom, a group represented by the following Chemical Formula (2), a group represented by the following Chemical Formula (3), or a group represented by the following Chemical Formula (2′); from one to eight of Z₁ to Z₁₆ each independently represent a group represented by the following Chemical Formula (2) or a group represented by Chemical Formula (2′), and at least one of these represents a group represented by the following Chemical Formula (2); and M represents two hydrogen atoms, a metal atom, a metal oxide, or a metal halide.

—X-A₁ Chemical Formula (2):

In the above Chemical Formula (2), X represents an oxygen atom or a sulfur atom; A₁ represents a phenyl group, a phenyl group having one to five substituents R, or a naphthyl group having one to seven substituents R; each of the substituents R independently represents a nitro group, COOR₁, OR₂ (wherein R₂ represents an alkyl group having 1 to 8 carbon atoms), a halogen atom, an aryl group, a cyano group, or an alkyl group having 1 to 8 carbon atoms which may be substituted with a halogen atom; and R₁ represents an alkyl group having 1 to 8 carbon atoms which may be substituted with an alkyloxy group having 1 to 8 carbon atoms, a halogen atom, or an aryl group.

R₃—OₙR₄ Chemical Formula (3):

In the above Chemical Formula (3), R₃ represents an alkylene group having 1 to 3 carbon atoms; R₄ represents an alkyl group having 1 to 8 carbon atoms; and n represents an integer from 1 to 4.

—OR′—OₗR″ Chemical Formula (2′):

In the above Chemical Formula (2′), R′ represents an alkylene group having 1 to 3 carbon atoms; R″ represents an alkyl group having 1 to 8 carbon atoms; and 1 represents an integer from 0 to 4.

In the present specification, the compound of Formula (1) may also be referred to simply as “phthalocyanine compound”.

In the present specification, since Z₁, Z₄, Z₅, Z₈, Z₉, Z₁₂, Z₁₃ and Z₁₆ in Formula (1) represent substituents that are substituted at the eight α-positions of the phthalocyanine nucleus, these substituents are also referred to as α-position substituents.

Similarly, since Z₂, Z₃, Z₆, Z₇, Z₁₀, Z₁₁, Z₁₄ and Z₁₅ in Formula (1) represent substituents that are substituted at the eight β-positions of the phthalocyanine nucleus, these substituents are also referred to as β-position substituents.

A colored composition and a colored photosensitive composition, each of which contains the phthalocyanine compound (1) and a yellow coloring material, have enhanced heat resistance and luminance, and can be suitably used in liquid crystal display devices or image sensors.

In the above Formula (1), each of Z₁ to Z₁₆ independently represents a hydrogen atom, a halogen atom, a group represented by the following Chemical Formula (2), a group represented by the following Chemical Formula (3), or a group represented by the following Chemical Formula (2′).

—X-A₁ Chemical Formula (2):

R₃—OₙR₄ Chemical Formula (3):

—OR′—OₗR″ Chemical Formula (2′):

At this time, Z₁ to Z₁₆ may be identical with or different from one another. From one to eight of Z₁ to Z₁₆ each independently represent a group represented by Chemical Formula (2) or a group represented by Chemical Formula (2′), and at least one of these is a group represented by Chemical Formula (2).

Examples of the halogen atom in Z₁ to Z₁₆ include a fluorine atom, a chlorine atom, a bromine atom, and an iodine atom, and among these, preferred examples include a fluorine atom and a chlorine atom, while a chlorine atom is more preferred.

In Chemical Formula (2), X represents an oxygen atom or a sulfur atom. X is preferably an oxygen atom. When X is an oxygen atom, the maximum absorption wavelength of the phthalocyanine compound thus obtainable can be shifted to the shorter wavelength side.

In Chemical Formula (2), A₁ represents a phenyl group, a phenyl group having one to five substituents R, or a naphthyl group having one to seven substituents R.

A₁ is preferably a phenyl group having one to five substituents R or a naphthyl group having one to seven substituents R, and more preferably a phenyl group having one to five substituents R.

The number of substituents of the phenyl group is from 1 to 5, but from the viewpoint of the gram extinction coefficient, the number of substituents is more preferably an integer from 1 to 3. When the substituent is a halogen atom, the number of substituents is preferably any of integers from 1 to 5. The number of substituents of the naphthyl group is from 1 to 7, but from the viewpoint of the gram extinction coefficient (absorbance per gram), the number of substituents is preferably from 1 to 5, more preferably from 1 to 3, and still more preferably 1 or 2.

The bonding position between the naphthyl group and X is not particularly limited, and the bonding position may be any of the 1-position (1-naphthyl group) or the 2-position (2-naphthyl group) shown below.

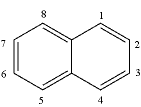

Similarly, the bonding position of a substituent to the naphthalene ring is also not particularly limited.

For example, when the bonding position between the naphthyl group and X is the 1-position (1-naphthyl group), the bonding position of a substituent to the naphthalene ring may be any of the 2-position, 3-position, 4-position, 5-position, 6-position, 7-position, or 8-position; however, in consideration of heat resistance, solvent solubility or the like, the bonding position is preferably the 2-position or the 3-position, and more preferably the 2-position. Furthermore, when the bonding position between the naphthyl group and X is the 2-position (2-naphthyl group), the bonding position of a substituent to the naphthalene ring may be any of the 1-position, 3-position, 4-position, 5-position, 6-position, 7-position, or 8-position; however, the bonding position is preferably the 3-position or 6-position, and in consideration of heat resistance, solvent solubility or the like, the 3-position is more preferred.

The substituent (hereinafter, also referred to as R) of the phenyl group or the naphthyl group is a nitro group, COOR₁, OR₂ (wherein R₂ represents an alkyl group having 1 to 8 carbon atoms), a halogen atom, an aryl group, a cyano group, or an alkyl group having 1 to 8 carbon atoms (at this time, the alkyl group may be substituted with a halogen atom). In this case, R₁ represents an alkyl group having 1 to 8 carbon atoms (in this case, the alkyl group may be substituted with an alkyloxy group having 1 to 8 carbon atoms, a halogen atom, or an aryl group), or a group represented by the following Chemical Formula (3).

When the phenyl group or the naphthyl group carries a plural number of the substituent R, plural R's may be identical with or different from one another.

R₃—OₙR₄ Chemical Formula (3):

In Chemical Formula (3), R₃ represents an alkylene group having 1 to 3 carbon atoms; R₄ represents an alkyl group having 1 to 8 carbon atoms; and n represents an integer from 1 to 4.

When R represents COOR₁, R₁ in COOR₁ represents an alkyl group having 1 to 8 carbon atoms which may be substituted, or a group represented by Chemical Formula (3).

When R₁ is an alkyl group having 1 to 8 carbon atoms, the alkyl group having 1 to 8 carbon atoms is preferably an alkyl group having 1 to 3 carbon atoms from the viewpoint of solvent solubility. Examples of the alkyl group having 1 to 8 carbon atoms include linear, branched or cyclic alkyl groups such as a methyl group, an ethyl group, an n-propyl group, an isopropyl group, an n-butyl group, an isobutyl group, a sec-butyl group, a t-butyl group, an n-pentyl group, an n-hexyl group, a cyclohexyl group, an n-heptyl group, an n-octyl group, and a 2-ethylhexyl group. The substituent that is optionally present in the alkyl group having 1 to 8 carbon atoms is an alkyloxy group having 1 to 8 carbon atoms, a halogen atom, or an aryl group.

Examples of the alkyloxy group having 1 to 8 carbon atoms that is optionally present, which is a substituent of the alkyl group, include linear, branched or cyclic alkyloxy groups such as a methoxy group, an ethoxy group, an n-propyloxy group, an isopropyloxy group, an n-butyloxy group, an isobutyloxy group, a sec-butyloxy group, a t-butyloxy group, an n-pentyloxy group, an n-hexyloxy group, a cyclohexyloxy group, an n-heptyloxy group, an n-octyloxy group, and a 2-ethylhexyloxy group. Among these, an alkyloxy group having 1 to 4 carbon atoms is preferred. Examples of the halogen atom that is optionally present, which is a substituent of the alkyl group, include a fluorine atom, a chlorine atom, a bromine atom, and an iodine atom. Among these, a fluorine atom or a chlorine atom is preferred. Examples of the aryl group that is optionally present, which is a substituent of the alkyl group, include a phenyl group, a p-methoxyphenyl group, a p-t-butylphenyl group, and a p-chlorophenyl group. Among these, a phenyl group is preferred. There may be a plural number of these substituents, and when there are plural substituents, the substituents may be of the same kind or may be of different kinds Even in the case of having substituents of the same kind, the substituents may be identical or different. The number of the substituents of the alkyl group is not particularly limited, but the number is preferably from 1 to 3, and more preferably 1 or 2.

In the case in which R₁ in COOR₁ is a group represented by Chemical Formula (3), R₃ in the group represented by Chemical Formula (3) is an alkylene group having 1 to 3 carbon atoms, from the viewpoint of the effect on ether solvent solubility.

Examples of the alkylene group having 1 to 3 carbon atoms include a methylene group, an ethylene group, an n-propylene group, and an isopropylene group. Preferred examples include an ethylene group and a propylene group.

Furthermore, R₄ in the group represented by Chemical Formula (3) is an alkyl group having 1 to 8 carbon atoms from the viewpoint of molecular weight, and is more preferably an alkyl group having 1 to 4 carbon atoms. Examples of the alkyl group having 1 to 8 carbon atoms include those described in the above-described section for R₁. n in the group represented by Chemical Formula (3) is an integer from 1 to 4 from the viewpoint of molecular weight, and is preferably an integer from 1 to 3.

When R is OR₂, R₂ in OR₂ represents an alkyl group having 1 to 8 carbon atoms, and preferably represents an alkyl group having 1 to 3 carbon atoms from the viewpoint of having favorable crystallinity and handleability of the dye.

Examples of the alkyl group having 1 to 8 carbon atoms represented by R₂ include the same substituents as those described for R₁.

When R is a halogen atom, examples of the halogen atom include a fluorine atom, a chlorine atom, a bromine atom, and an iodine atom, and the halogen atom is preferably a fluorine atom, a chlorine atom, or an iodine atom. Among them, the halogen atom is preferably a chlorine atom or a fluorine atom because the molecular weight of the dye becomes smaller, and the gram extinction coefficient is increased.

When R is an aryl group, examples of the aryl group include aryl groups such as a phenyl group, a p-methoxyphenyl group, a p-t-butylphenyl group, and a p-chlorophenyl group.

Among them, a phenyl group is preferred because the molecular weight of the dye becomes smaller, and the gram extinction coefficient is increased.

When R is an alkyl group, examples of the alkyl group having 1 to 8 carbon atoms which may be substituted include those alkyl groups exemplified in the case where R₁ is an alkyl group having 1 to 8 carbon atoms.

Preferably, the alkyl group is an alkyl group having 1 to 3 carbon atoms, from the viewpoint of having favorable crystallinity and handleability of the dye.

Examples of the halogen atom that is optionally present, which is a substituent of the alkyl group, include a fluorine atom, a chlorine atom, a bromine atom, and an iodine atom. Among these, a fluorine atom or a chlorine atom is preferred. There may be a plural number of the halogen atom as a substituent of the alkyl group, and when there are plural halogen atoms, the halogen atoms may be identical or different. The number of the substituents of the alkyl group is not particularly limited, but the number is preferably 1 to 3.

In Chemical Formula (2′), R′ represents an alkylene group having 1 to 3 carbon atoms, from the viewpoints of the effect on ether solubility and of the molecular weight.

Examples of the alkylene group having 1 to 3 carbon atoms include those exemplified in the section for R₃.

Preferred examples are an ethylene group and a propylene group. R″ represents an alkyl group having 1 to 8 carbon atoms, and preferably an alkyl group having 1 to 2 carbon atoms, from the viewpoints of the effect on ether solubility, and of the molecular weight. Examples of the alkyl group having 1 to 8 carbon atoms include those exemplified in the section for R₁. 1 represents an integer from 0 to 4, and more preferably an integer of 1 or 2, from the viewpoints of the effect on ether solubility, and of the molecular weight.

In regard to the above Formula (1), M represents a non-metal, a metal, a metal oxide, or a metal halide. Here, a non-metal means an atom other than a metal, for example, two hydrogen atoms. Furthermore, examples of the metal include iron, magnesium, nickel, cobalt, copper, palladium, zinc, vanadium, titanium, indium, and tin. Examples of the metal oxide include titanyl and vanadyl. Examples of the metal halide include aluminum chloride, indium chloride, germanium chloride, tin(II) chloride, tin(IV) chloride, and silicon chloride. M is preferably a metal, a metal oxide, or a metal halide, and specific examples include copper, zinc, cobalt, nickel, iron, vanadyl, titanyl, indium chloride, and tin(II) chloride. More preferred examples include copper, vanadyl, and zinc, even more preferred examples include zinc and copper, and most preferred is zinc. When the central metal is zinc or copper, it is preferable because the compound acquires high heat resistance. Also, when the central metal is zinc, it is particularly preferable because the transmittance near 520 nm to 545 nm, which is the wavelength range for green color, is higher than the case of copper, and luminance can be increased when a color filter is produced from the compound. Also, it is particularly preferable because the compound has high solvent solubility in general-purpose solvents such as acetone, methanol and methyl cellosolve, and has high solubility in resins and high contrast.

In the phthalocyanine compound (1), from one to eight of Z₁ to Z₁₆ each independently represent a group represented by Chemical Formula (2) or Chemical Formula (2′), and among these, at least one is a group represented by Chemical Formula (2). Those other than the groups represented by Chemical Formula (2) or Chemical Formula (2′) among Z₁ to Z₁₆, each independently represent a hydrogen atom or a halogen atom.

In a suitable embodiment of the phthalocyanine compound (1), from one to eight of Z₁ to Z₁₆ each independently represent a group represented by Chemical Formula (2) or Chemical Formula (2′), and the remainder each independently represent a hydrogen atom or a chlorine atom. More preferably, from two to six of Z₁ to Z₁₆ represent groups each represented by Chemical Formula (2) or Chemical Formula (2′), and the remainder each independently represent a hydrogen atom or a chlorine atom.

(Method of Producing Phthalocyanine Compound (1))

The method of producing the phthalocyanine compound (1) of the invention is not particularly limited, and any conventionally known method can be used as appropriate. However, preferably, a method of subjecting a phthalonitrile compound and a metal salt to a cyclization reaction in a dissolved state or in an organic solvent can be particularly preferably used. A particularly preferred embodiment of the production method of the phthalocyanine compound (1) of the invention will be described below. However, the invention is not intended to be limited to the preferred embodiment described below.

That is, the phthalocyanine compound of the invention can be produced by subjecting a phthalonitrile compound (1) represented by the following Formula (I):

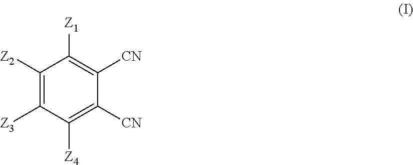

a phthalonitrile compound (2) represented by the following Formula (II):

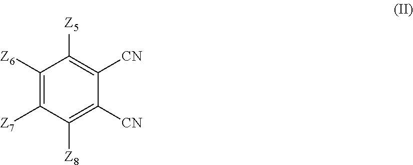

a phthalonitrile compound (3) represented by the following Formula (III):

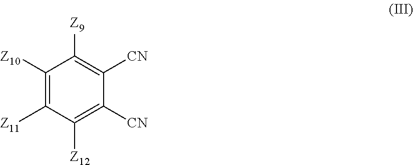

and a phthalonitrile compound (4) represented by the following Formula (IV):

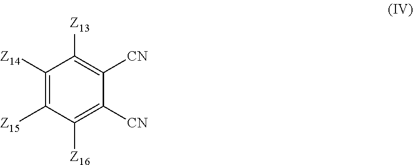

to a cyclization reaction together with one selected from the group consisting of a metal, a metal oxide, a metal carbonyl, a metal halide, and an organic acid metal (in the present specification, these are collectively referred to as “metal compounds”).

Meanwhile, in the above Formulas (I) to (IV), Z₁ to Z₁₆ are defined by the structure of the desired phthalocyanine compound (1). Specifically, Z₁ to Z₁₆ in the above Formulas (I) to (IV) respectively have the same definitions as Z₁ to Z₁₆ in Formula (1) shown above, and therefore, further descriptions will not be repeated here.

In regard to the cyclization reaction, synthesis can be carried out by a conventionally known method, such as the method described in JP-A No. S64-45474.

In the embodiment described above, the cyclization reaction is preferably carried out such that phthalonitrile compounds of Formula (I) to Formula (IV) are caused to react with any one selected from the group consisting of a metal, a metal oxide, a metal carbonyl, a metal halide, and an organic acid metal, in a dissolved state or in an organic solvent. The metal, metal oxide, metal carbonyl, metal halide and organic acid metal that can be used at this time are not particularly limited as long as a moiety corresponding to M of the phthalocyanine compound (1) of Formula (1) obtainable after the reaction can be obtained, and examples include metals such as iron, copper, zinc, vanadium, titanium, indium, and tin, which are listed in the section for M in the above Formula (1); metal halides such as chlorides, bromides and iodides of the metals; metal oxides such as vanadium oxide, titanium oxide, and copper oxide; organic acid metals such as acetates; complex compounds such as acetylacetonate; and metal carbonyls such as iron carbonyl. Specific examples include metals such as iron, copper, zinc, vanadium, titanium, indium, magnesium and tin; metal halides such as chlorides, bromides and iodides of the metals, for example, vanadium chloride, titanium chloride, copper chloride, zinc chloride, cobalt chloride, nickel chloride, iron chloride, indium chloride, aluminum chloride, tin chloride, gallium chloride, germanium chloride, magnesium chloride, copper iodide, zinc iodide, cobalt iodide, indium iodide, aluminum iodide, gallium iodide, copper bromide, zinc bromide, cobalt bromide, aluminum bromide, and gallium bromide; metal oxides such as vanadium monoxide, vanadium trioxide, vanadium tetroxide, vanadium pentoxide, titanium dioxide, iron monoxide, iron sesquioxide, triiron tetroxide, manganese oxide, nickel monoxide, cobalt monoxide, cobalt sesquioxide, cobalt dioxide, cuprous oxide, cupric oxide, copper sesquioxide, palladium oxide, zinc oxide, germanium monoxide, and germanium dioxide; organic acid metals such as copper acetate, zinc acetate, cobalt acetate, copper benzoate, and zinc benzoate; complex compounds such as acetylacetonates; and metal carbonyls such as cobalt carbonyl, iron carbonyl, and nickel carbonyl. Among these, preferred examples include metals, metal oxides, and metal halides; more preferred examples include metal halides; still more preferred examples include vanadium iodide, copper iodide, and zinc iodide; particularly preferred examples include copper iodide and zinc iodide; and most preferred is zinc iodide. In the case of using zinc iodide, the central metal is constituted by zinc. The reason why it is suitable to use iodides among metal halides is that halides have excellent solubility in solvents or resins, and the spectra of phthalocyanine compounds thus obtainable are sharp and are likely to fall in the range of from 640 nm to 750 nm, which are desired wavelengths. The detailed mechanism in which the spectrum becomes sharp when an iodide is used at the time of a cyclization reaction, is not clearly understood, but it is speculated that when an iodide is used, iodine remaining in the phthalocyanine compound after the reaction causes a certain interaction with the phthalocyanine compound, and iodine comes to exist between layers of the phthalocyanine compound. However, the mechanism is not intended to be limited to the mechanism described above. In order to obtain the same effect as that obtainable in a case in which a metal iodide is used in the cyclization reaction, the phthalocyanine compound thus obtained may be treated with iodide.

Furthermore, in regard to the embodiment described above, the cyclization reaction can be carried out solventlessly, but it is preferable to carry out the reaction using an organic solvent. The organic solvent may be any solvent having low reactivity with the phthalonitrile compounds as starting raw materials, and preferably an inert solvent that does not exhibit reactivity, and examples include inert solvents such as benzene, toluene, xylene, nitrobenzene, monochlorobenzene, o-chlorotoluene, dichlorobenzene, trichlorobenzene, 1-chloronaphthalene, 1-methylnaphthalene, ethylene glycol, and benzonitrile; alcohols such as methanol, ethanol, 1-propanol, 2-propanol, 1-butanol, 1-hexanol, 1-pentanol, and 1-octanol; and aprotic polar solvents such as pyridine, N,N-dimethylforamide, N,N-dimethylacetamide, N-methyl-2-pyrrolidinone, N,N-dimethylacetophenone, triethylamine, tri-n-butylamine, dimethyl sulfoxide, and sulfolane.

Among these, preferred examples that may be used include 1-chloronaphthalene, 1-methylnaphthalene, 1-octanol, dichlorobenzene, and benzonitrile; and more preferred examples include 1-octanol, dichlorobenzene, and benzonitrile. These solvents may be used singly, or in combination of two or more kinds thereof.

The conditions for the reaction between the phthalonitrile compounds of Formulas (I) to (IV) and a metal compound in the embodiment described above are not particularly limited as long as the reaction conditions are conditions allowing the reaction to proceed, but for example, the phthalonitrile compounds (1) to (4) are introduced in a total amount in the range of 1 part to 500 parts by mass, and preferably 10 parts to 350 parts by mass, with respect to 100 parts by mass of the organic solvent, and the metal compound is introduced preferably in an amount in the range of 0.8 moles to 2.0 moles, and more preferably 0.8 moles to 1.5 moles, with respect to 4 moles of the phthalonitrile compound. On the occasion of cyclization, although not particularly limited, the reaction is carried out at a reaction temperature in the range of preferably 30° C. to 250° C., and more preferably 80° C. to 200° C. The reaction time is not particularly limited, but is preferably 3 hours to 20 hours. Meanwhile, after the reaction, filtration, washing, and drying are carried out according to a conventionally known method of synthesizing a phthalocyanine compound, and thereby phthalocyanine compounds that can be used in the subsequent processes can be obtained efficiently at high purity.

In the embodiment described above, the phthalonitrile compounds of Formulas (I) to (IV) as starting raw materials can be synthesized by conventionally existing methods, and commercially available products can also be used.

Preferred examples of the phthalocyanine compound (1) include the compounds described below. However, the phthalocyanine compounds of the invention are not intended to be limited to these. In regard to the abbreviations of the compounds described below, Pc represents the phthalocyanine nucleus; Zn represents the central metal; a substituent that is substituted at the a-position is indicated immediately after Pc; a substituent that is substituted at the β-position is indicated after the substituent that is substituted at the a-position; and then a substituent that is not dependent on the position of substitution is indicated. x and y are each a positive number at which the number of substituents is a positive number of 0 or greater.

[ZnPc-{α-(4-COOC₂H₄OCH₃)C₆H₄O}ₓ, {β-(4-COOC₂H₄OCH₃)C₆H₄O}_{3.8-x}H_{0.8}Cl_{11.4}]

[ZnPc-{α-(4-COOC₂H₄OCH₃)C₆H₄O}ₓ, {a-(2,6-Cl₂)C₆H₃S}_{y}, {β-(4-COOC₂H₄OCH₃)C₆H₄O}_{2.88-x}, {β-(2,6-Cl₂)C₆H₃S}_{0.72-y}, H_{1.6} Cl_{10.8}]

[ZnPc-{α-(4-COOC₂H₄OCH₃)C₆H₄O}ₓ, {β-(4-COOC₂H₄OCH₃)C₆H₄O}_{3.8-x}, (β-NO₂)_{0.2}H_{0.6}Cl_{11.4}]

[Zn(C₃₂N_{8.2})-{α-COOC₂H₄OCH₃)C₆H₄O}ₓ, {β-(4-COOC₂H₄OCH₃)C₆H₄O}_{3.8-x}H_{0.6}Cl_{11.4}]

[Zn(C_{32.8}N₈)-{α-(4-COOC₂H₄OCH₃)C₆H₄O}ₓ, {β-(4-COOC₂H₄OCH₃)C₆H₄O}_{3.8-x}H_{1.2}Cl_{11.4}]

[Zn(C_{32.8}N₈)-{α-(4-COOC₂H₄OCH₃)C₆H₄O}ₓ, {β-(4-COOC₂H₄OCH₃)C₆H₄O}_{3.8-x}H_{0.8}Cl_{11.4}Br_{0.4}]

[ZnPc-{α-(4-COOC₂H₄OCH₃)C₆H₄O}ₓ, {β-(4-COOC₂H₄OCH₃)C₆H₄O}_{3.8-x}, (β-NH₂)_{0.2}H_{0.6}Cl_{11.4}]

[ZnPc-{α-(4-COOC₂H₄OCH₃)C₆H₄O}ₓ, {β-(4-COOC₂H₄OCH₃)C₆H₄O}_{3.8-x}, (β-OH)_{0.2}H_{0.6}Cl_{11.4}]

[ZnPc-{α-(4-COOC₂H₄OCH₃)C₆H₄O}ₓ, {β-(4-COOC₂H₄OCH₃)C₆H₄O}_{3.8-x}, (β-C(CH₃)₃)_{0.2}H_{0.6}Cl_{11.4}]

[ZnPc-{α-(4-COOC₂H₄OCH₃)C₆H₄O}ₓ, {β-(4-COOC₂H₄OCH₃)C₆H₄O}_{3.8-x}H_{0.4}Cl_{11.8}]

[Zn(C₃₂N_{8.08})-{α-(4-COOC₂H₄OCH₃)C₆H₄O}ₓ, {β-(4-COOC₂H₄OCH₃)C₆H₄O}_{3.96-x}H_{0.08}Cl_{11.88}]

[ZnPc-{α-(4-COOC₂H₄OCH₃)C₆H₄O}ₓ, {β-(4-COOC₂H₄OCH₃)C₆H₄O}_{3.8-x}H_{0.8}F_{11.4}]

[ZnPc-α-{(CH₃CH(OCH₃)C₂H₄OOC)C₆H₄S}_{0.2}, {α-(4-COOC₂H₄OCH₃)C₆H₄O}ₓ, {β-(4-COOC₂H₄OCH₃)C₆H₄O}_{3.8-x}H_{0.6} Cl_{11.4}]

[ZnPc-{α-(4-SO₃C₂H₄OCH₃)C₆H₄O}ₓ, {β-(4-SO₃C₂H₄OCH₃)C₆H₄O}_{3.8-x}H_{0.8}Cl_{11.4}]

[ZnPc-{α-(4-COOCH₃)C₆H₄O}ₓ, {β-(4-COOCH₃)C₆H₄O}_{5.7-x}H_{0.8}Cl_{9.5}]

[ZnPc-{α-(4-COOC₂H₄OCH₃)C₆H₄O}ₓ, {β-(4-COOC₂H₄OCH₃)C₆H₄O}_{2.28-x}H_{0.8}Cl_{12.92}]

[ZnPc-{α-(4-COOC₂H₄OCH₃)C₆H₄O}ₓ, {β-(4-COOC₂H₄OCH₃)C₆H₄O}_{1.14-x}H_{0.8}Cl_{14.06}]

[ZnPc-{α-(4-COOC₂H₄OCH₃)C₆H₄O}ₓ, {α-(2-OCH₃-4-COOC₂H₄OCH₃)C₆H₃O}_{y}, {β-(4-COOC₂H₄OCH₃)C₆H₄O}_{2.72-x}, {β-(2-OCH₃-4-COOC₂H₄OCH₃)C₆H₃O}_{0.68-y}H_{2.4}Cl_{10.2}]

[ZnPc-{β-(2-COOC₂H₄OCH₃)C₁₀H₈-6-O}ₓ, {β-(2-COOC₂H₄OCH₃)C₁₀H₈-6-O}_{3.8-x}H_{0.8}Cl_{11.4}]

[ZnPc-{α-(4-COOC₂H₄OCH₃)C₆H₄O}ₓ, {α-(4-CN)C₆H₄O}_{0.96}, {β-(4-COOC₂H₄OCH₃)C₆H₄O}_{3.04-x}H_{2.88}Cl_{9.12}]

[ZnPc-{α-(4-COOC₂H₄OCH₃)C₆H₄O}ₓ, {α-(2-C₆H₅)C₆H₄O}_{y}, {β-(4-COOC₂H₄OCH₃)C₆H₄O}_{3.42-x}, {β-(2-C₆H₅)C₆H₄O}_{0.38-y}H_{0.8} Cl_{11.4}]
[ZnPc-{α-(4-COOC₂H₄OCH₃)C₆H₄O}ₓ, {α-(2-COOCH₃)C₆H₄S}_{y}, {β-(4-COOC₂H₄OCH₃)C₆H₄O}_{3.04-x}, {β-(2-COOCH₃)C₆H₄S}_{0.76-y}H_{0.8}Cl_{11.4}]

[ZnPc-{α-(4-COOC₂H₄OCH₃)C₆H₄O}ₓ, {α-(4-OCH₃)C₆H₄O}_{y}, {β-(4-COOC₂H₄OCH₃)C₆H₄O}_{3.42-x}, {β-(4-OCH₃)C₆H₄O}_{0.38-y}H_{0.8}Cl_{11.4}]

[ZnPc-{α-(4-COOC₂H₄OCH₃)C₆H₄O}ₓ, {α-(2-C(CH₃)₃)C₆H₄O}_{y}, {β-(4-COOC₂H₄OCH₃)C₆H₄O}_{3.42-x}, {β-(2-C(CH₃)₃)C₆H₄O}_{0.38-y}H_{0.8}Cl_{11.4}]

[ZnPc-{α-(4-COOC₂H₄OCH₃)C₆H₄O}ₓ, {α-(3-COOC₂H₅)C₆H₄O}_{y}, {β-(4-COOC₂H₄OCH₃)C₆H₄O}_{2.66-x}, {β-(3-COOC₂H₅)C₆H₄O}_{1.14-y}H_{0.8}Cl_{11.4}]

[ZnPc-{α-(4-COOC₂H₄OCH₃)C₆H₄O}ₓ, {α-C₆H₅O}_{y}, {β-(4-COOC₂H₄OCH₃)C₆H₄O}_{1.9-x}{β-C₆H₅O}_{0.76-y}H_{0.8}Br_{1.22}Cl_{11.32}]

[Yellow Coloring Material]

Regarding the yellow coloring material used in the invention, known pigments (for example, yellow pigments listed for the pigment that will be described below) can be used. Specifically, C.I. Pigment Yellow 138 and 150 are preferred from the viewpoint of color reproduction.

In addition to this, compounds represented by Formula (6) and Formula (7) will be explained.

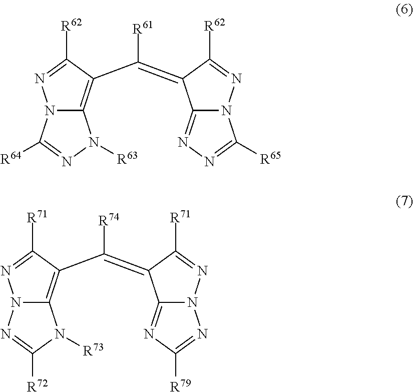

wherein in Formulas (6) and (7), each of R⁶¹ to R⁶⁵, R⁷¹ to R⁷⁴, and R⁷⁹ independently represents a hydrogen atom, an alkyl group, an alkoxy group, an alkoxycarbonyl group, a carbamoyl group, a sulfamoyl group, a cyano group, an aryl group, or a heteroaryl group.

Preferred substituents in the compounds represented by Formulas (6) and (7) will be explained.

The alkyl group represented by R⁶¹ to R⁶⁵, R⁷¹ to R⁷⁴ and R⁷⁹ is an alkyl group having 1 to 48 carbon atoms (more preferably, 1 to 18 carbon atoms), and may be any of a linear group, a branched group, or a cyclic group. Examples include a methyl group, an ethyl group, a propyl group, an isopropyl group, a butyl group, a t-butyl group, a pentyl group, a hexyl group, a heptyl group, an octyl group, a 2-ethylhexyl group, a dodecyl group, a hexadecyl group, a cyclopropyl group, a cyclopentyl group, a cyclohexyl group, a 1-norbornyl group, and a 1-adamantyl group, and preferred examples include a methyl group, an ethyl group, a propyl group, an isopropyl group, a butyl group, a t-butyl group, a pentyl group, a hexyl group, a heptyl group, an octyl group, and a 2-ethylhexyl group.

The alkoxy group represented by R⁶¹ to R⁶⁵, R⁷¹ to R⁷⁴, and R⁷⁹ is an alkoxy group having 1 to 48 carbon atoms (more preferably, 1 to 12 carbon atoms), and examples include a methoxy group, an ethoxy group, a 1-butoxy group, a 2-butoxy group, an isopropoxy group, a t-butoxy group, a dodecyloxy group, and a cycloalkyloxy group (for example, a cyclopentyloxy group and a cyclohexyloxy group), while preferred examples include a methoxy group, an ethoxy group, a 1-butoxy group, a 2-butoxy group, an isopropoxy group, and a t-butoxy group.

The alkoxycarbonyl group represented by R⁶¹ to R⁶⁵, R⁷¹ to R⁷⁴, and R⁷⁹ is an alkoxycarbonyl group having 2 to 48 carbon atoms (more preferably, 2 to 12 carbon atoms), and examples include a methoxycarbonyl group, an ethoxycarbonyl group, an octadecyloxycarbonyl group, and a cyclohexyloxycarbonyl group, while preferred examples include a methoxycarbonyl group and an ethoxycarbonyl group.

The carbamoyl group represented by R⁶¹ to R⁶⁵, R⁷¹ to R⁷⁴, and R⁷⁹ is a carbamoyl group having 1 to 48 carbon atoms (more preferably, 1 to 12 carbon atoms), and examples include a carbamoyl group, an N,N-diethylcarbamoyl group, an N-ethyl-N-octylcarbamoyl group, an N,N-dibutylcarbamoyl group, an N-propylcarbamoyl group, an N-phenylcarbamoyl group, an N-methyl-N-phenylcarbamoyl group, and an N,N-dicyclohexylcarbamoyl group, while preferred examples include an N-ethyl-N-octylcarbamoyl group, an N,N-dibutylcarbamoyl group, an N-propylcarbamoyl group, and an N-phenylcarbamoyl group.

The sulfamoyl group represented by R⁶¹ to R⁶⁵, R⁷¹ to R⁷⁴, and R⁷⁹ is a sulfamoyl group having 32 or fewer carbon atoms (more preferably, 16 or fewer carbon atoms), and examples include a sulfamoyl group, an N,N-dipropylsulfamoyl group, an N-ethyl-N-dodecylsulfamoyl group, an N-ethyl-N-hexylsulfamoyl group, an N-ethyl-N-phenylsulfamoyl group, and an N-cyclohexylsulfamoyl group, while preferred examples include an N-ethyl-N-hexylsulfamoyl group, an N-ethyl-N-phenylsulfamoyl group, and an N-cyclohexylsulfamoyl group.

The aryl group represented by R⁶¹ to R⁶⁵, R⁷¹ to R⁷⁴, and R⁷⁹ is an aryl group having 6 to 48 carbon atoms (more preferably, 6 to 12 carbon atoms), and examples include a phenyl group and a naphthyl group, while preferred examples include a phenyl group.

The heteroaryl group represented by R⁶¹ to R⁶⁵, R⁷¹ to R⁷⁴, and R⁷⁹ is a heteroaryl group having 1 to 32 carbon atoms (more preferably, 1 to 12 carbon atoms), and examples include a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group, while preferred examples include a 2-benzothiazolyl group, a 1-imidazolyl group, a 1-pyrazolyl group, and a benzotriazol-1-yl group.

Each of R⁶² and R⁷¹ is preferably an alkyl group having 1 to 8 carbon atoms and having a substituent, an aryl group having 6 to 12 carbon atoms and having a substituent, or a cyano group, and is more preferably a methyl group, an ethyl group, an isopropyl group, a t-butyl group, a phenyl group, or an o-methylphenyl group.

Each of R⁶³ and R⁷³ preferably represents a hydrogen atom, and each of R⁶¹ and R⁷⁴ preferably represents a hydrogen atom or a methyl group, and more preferably a hydrogen atom. Regarding R⁶⁴, R⁶⁵, R⁷² and R⁷⁹, the structures are not particularly limited, but each of R⁶⁴, R⁶⁵, R⁷² and R⁷⁹ is preferably an alkoxycarbonyl group, a carbamoyl group, or a sulfamoyl group, each of which has a substituted alkyl group, a PEO (polyethylene glycol) chain, a PPO (polypropylene glycol) chain, an ammonium salt, or a polymerizable group, and is more preferably a sulfamoyl group.

The compound represented by Formula (6) or (7) is more preferably a compound represented by the following Formula (8) or (9).

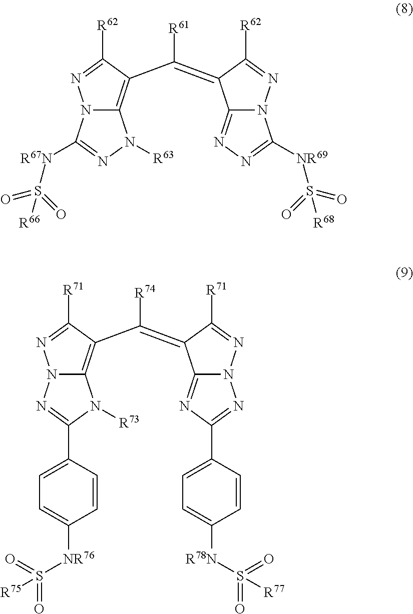

wherein in Formulas (8) and (9), R⁶¹ to R⁶³, R⁷¹, R⁷³, and R⁷⁴ have the same definitions as R⁶¹ to R⁶³, R⁷¹, R⁷³, and R⁷⁴ in Formulas (6) and (7), respectively. Each of R⁶⁷, R⁶⁹, R⁷⁶ and R⁷⁸ independently represents a hydrogen atom, or an alkyl group having 1 to 48 carbon atoms, and each of R⁶⁶, R⁶⁸, R⁷⁵ and R⁷⁷ independently represents an alkyl group having 1 to 48 carbon atoms, an aryl group having 6 to 48 carbon atoms, or a heteroaryl group having 1 to 32 carbon atoms.

Preferred substituents in the compounds represented by Formulas (8) and (9) will be explained.

Specific examples and a preferred range of R⁶¹ to R⁶³, R⁷¹, R⁷³ and R⁷⁴ have the same definitions as the specific examples and the preferred range of R⁶¹ to R⁶³, R⁷¹, R⁷³ and R⁷⁴ in Formulas (6) and (7), respectively.

Specific examples and a preferred range of the alkyl group represented by R⁶⁷, R⁶⁹, R⁷⁶ and R⁷⁸ have the same definitions as the specific examples and a preferred range of the alkyl group represented by R⁶¹ to R⁶⁵, R⁷¹ to R⁷⁴, and R⁷⁹ in Formulas (6) and (7), respectively. Furthermore, specific examples and a preferred range of the alkyl group represented by R⁶⁶, R⁶⁸, R⁷⁵, and R⁷⁷ have the same definitions as the specific examples and a preferred range of the alkyl group represented by R⁶¹ to R⁶⁸, R⁷¹ to R⁷⁴, and R⁷⁹ in Formulas (6) and (7), respectively.

Specific examples and a preferred range of the aryl group represented by R⁶⁶, R⁶⁸, R⁷⁵ and R⁷⁷ have the same definitions as the specific examples and a preferred range of the aryl group represented by R⁶¹ to R⁶⁵, R⁷¹ to R⁷⁴, and R⁷⁹ in Formulas (6) and (7), respectively.

Specific examples and a preferred range of the heteroaryl group represented by R⁶⁶, R⁶⁸, R⁷⁵ and R⁷⁷ also have the same definitions as the specific examples and a preferred range of the heteroaryl group represented by R⁶¹ to R⁶⁵, R⁷¹ to R⁷⁴, and R⁷⁹ in Formulas (6) and (7), respectively.

Particularly preferred examples of R⁶² and R⁷¹ include a methyl group, an ethyl group, an isopropyl group, a t-butyl group, a phenyl group, and an o-methylphenyl group, and each of R⁶¹, R⁶³, R⁷³ and R⁷⁴ is particularly preferably a hydrogen atom.

Particularly preferred substituents of the dyes represented by Formulas (8) and (9) will be explained. Each of R⁶⁷, R⁶⁹, R⁷⁶ and R⁷⁸ preferably represents a hydrogen atom. Each of R⁶⁶, R⁶⁸, R⁷⁵ and R⁷⁷ preferably represents a structure having a substituted alkyl group, a PEO (polyethylene glycol) chain, a PPO (polypropylene glycol) chain, an ammonium salt, or a polymerizable group, and more preferably represents an alkyl group having 2 to 8 carbon atoms, or a group having a methacrylic acid group on an alkyl chain.

Next, specific examples of the dyes represented by Formulas (6) and (7) will be shown below. However, the invention is not intended to be limited to these.

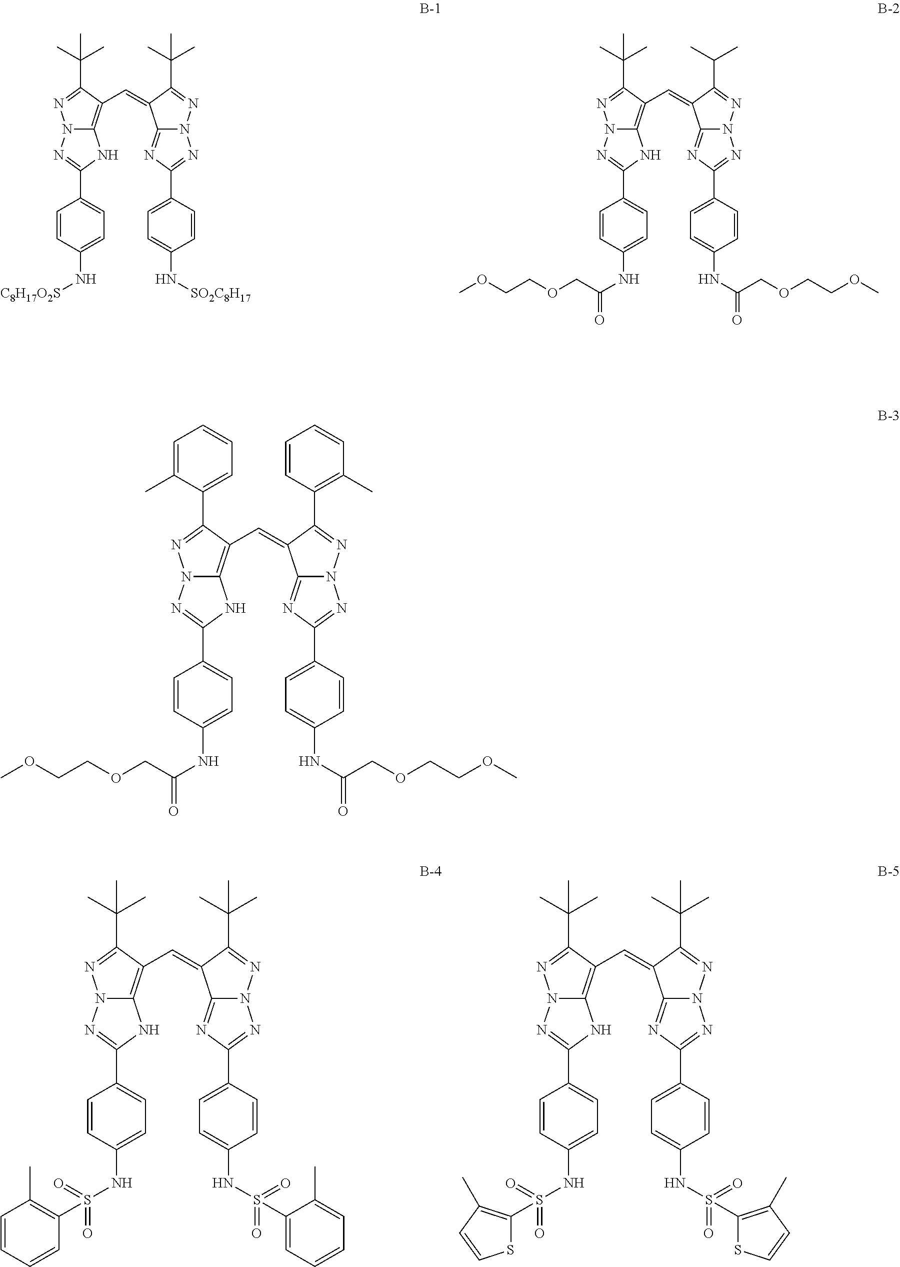

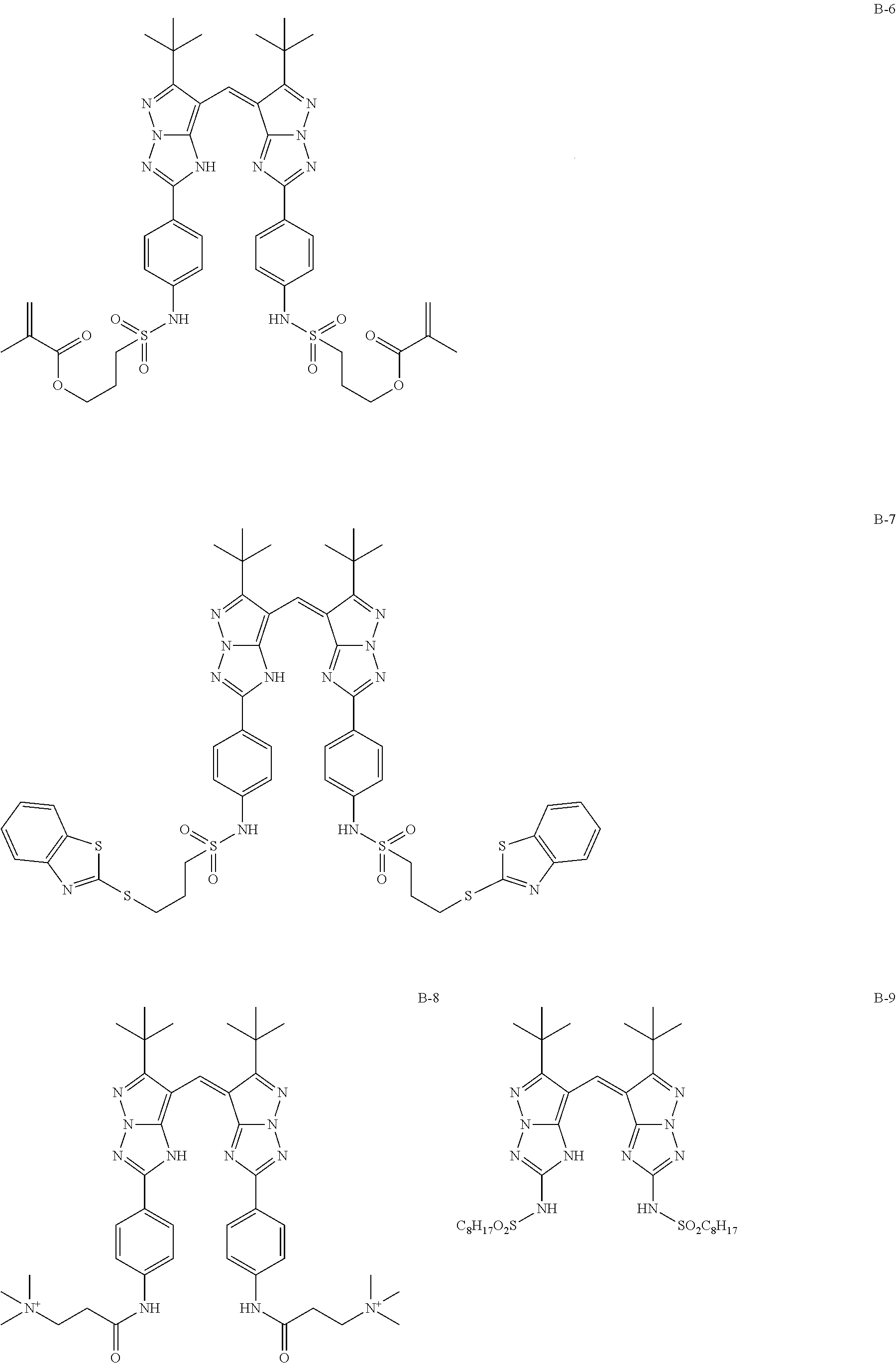

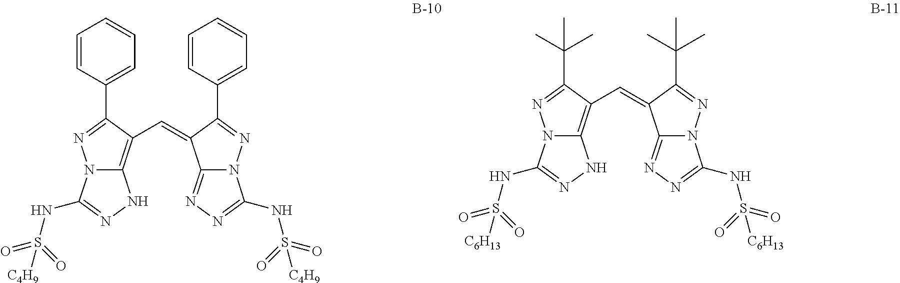

[Green Pigment]

Regarding the green pigment used in the invention, any known pigment can be used, but from the viewpoint of heat resistance, a phthalocyanine-based pigment is preferred.

Specific examples of the green pigment used in the invention include C.I. Pigment Green 7, 36 and 58. However, the invention is not intended to be limited to these.

[Preferred Combinations and Mixing Ratios]

According to the invention, in regard to the combination of the phthalocyanine compound of Formula (1) and the yellow coloring material, the content ratio (mass ratio) of the phthalocyanine compound and the yellow coloring material may vary depending on the compounds selected, but the content ratio is preferably from 5% to 300%, and more preferably from 20% to 300%.

Meanwhile, the content of the green pigment in the case of using the green pigment according to the invention is preferably from 1% by mass to 40% by mass, more preferably from 5% by mass to 35% by mass, and still more preferably 10% by mass to 30% by mass, with respect to the total solid content of the colored photosensitive composition, from the viewpoints of heat resistance, color reproducibility and luminance.

[Dye]

The colored composition may include a dye to the extent that the effects of the invention are not impaired.

The dye used in the invention can be used without any particular limitations, and can be selected from known solvent-soluble dyes and the like.

Examples include the coloring materials described in JP-A No. S64-90403, JP-A No. S64-91102, JP-A No. H01-94301, JP-A No. H06-11614, Japanese Registered Patent No. 2592207, U.S. Pat. No. 4,808,501, U.S. Pat. No. 5,667,920, U.S. Pat. No. 5,059,500, JP-A No. H05-333207, JP-A No. H06-35183, JP-A No. H06-51115, and JP-A No. H06-194828.

In regard to the chemical structure, azo-based dyes such as anilinoazo-based, arylazo-based and pyrazolotriazoleazo dyes; triphenylmethane-based dyes, anthraquinone-based dyes, anthrapyridone-based dyes, benzylidene-based dyes, oxonol-based dyes, cyanine-based dyes, phenothiazine-based dyes, pyrrolopyrazoleazomethine-based dyes, xanthene-based dyes, phthalocyanine-based dyes, benzopyran-based dyes, and indigo-based dyes can be used.

[Pigment]

Regarding the yellow pigment used in the invention, various conventionally known organic pigments can be used as explained in connection with the yellow coloring material described above.

Furthermore, when it is considered that the pigment used in the invention preferably has high transmittance, it is preferable to use a pigment having a particle diameter as small as possible and having a fine particle size, and in consideration of handleability, a pigment having an average particle size of preferably from 0.01 μm to 0.3 μm, and more preferably from 0.01 μm to 0.15 μm, is used. When the particle diameter is in the range described above, it is effective in forming a color filter which has high transmittance and favorable color characteristics, and exhibits high contrast.

Examples of the yellow pigment include C.I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214.

The pigments (green pigment and yellow pigment) used in the invention may be subjected to a micronization treatment as necessary.

For the micronization of an organic pigment, it is preferable to use a method including a process of triturating an organic pigment together with a water-soluble organic solvent and a water-soluble inorganic salt as a highly viscous liquid composition.

According to the invention, it is more preferable to use the following method of the micronization of an organic pigment.

That is, first, a mixture (liquid composition) of an organic pigment, a water-soluble organic solvent, and a water-soluble inorganic salt is subjected to strong shear force using a kneading machine such as a double roll mill, a triple roll mill, a ball mill, a Tron mill, a Disper, a kneader, a co-kneader, a homogenizer, a blender, or a single-screw or twin-screw extruder, to thereby triturate the organic pigment in the mixture, and then this mixture is introduced into water and is slurrified using a stirrer or the like. Subsequently, this slurry is filtered and washed with water to remove the water-soluble organic solvent and the water-soluble inorganic salt, and then the residue is dried. A micronized organic pigment is thus obtained in this method.

Examples of the water-soluble organic solvent used in the micronization method described above include methanol, ethanol, isopropanol, n-propanol, isobutanol, n-butanol, ethylene glycol, diethylene glycol, diethylene glycol monomethyl ether, diethylene glycol monoethyl ether, diethylene glycol monobutyl ether, propylene glycol, and propylene glycol monomethyl ether acetate.

Furthermore, benzene, toluene, xylene, ethylbenzene, chlorobenzene, nitrobenzene, aniline, pyridine, quinoline, tetrahydrofuran, dioxane, ethyl acetate, isopropyl acetate, butyl acetate, hexane, heptane, octane, nonane, decane, undecane, dodecane, cyclohexane, methylcyclohexane, halogenated hydrocarbons, acetone, methyl ethyl ketone, methyl isobutyl ketone, cyclohexanone, dimethylformamide, dimethyl sulfoxide, N-methylpyrrolidone, and the like may also be used, as long as the organic solvent adsorbs to the pigment and is not lost into wastewater when used in a small amount. Furthermore, a mixture of two or more kinds of solvents may also be used if necessary.

The amount of use of these water-soluble organic solvents is preferably in the range of from 50% by mass to 300% by mass, and more preferably in the range of from 100% by mass to 200% by mass with respect to the organic pigment.

Furthermore, examples of the water-soluble inorganic salt that may be used in the invention include sodium chloride, potassium chloride, calcium chloride, barium chloride, and sodium sulfate.

The amount of use of the water-soluble inorganic salt is preferably from one time to 50 times by mass the amount of the organic pigment, and although a larger amount of use of the water-soluble inorganic salt gives a better trituration effect, a more preferred amount from the viewpoint of productivity is from one time to 10 times by mass.

Furthermore, it is preferable that the moisture content in the liquid composition to be triturated is 1% by mass or less, in order to prevent dissolution of the water-soluble inorganic salt.

According to the invention, when a liquid composition including an organic pigment, a water-soluble organic solvent, and a water-soluble inorganic salt is triturated, a wet pulverization apparatus such as the kneading machine described above may be used. There are no particular limitations on the operating conditions for this wet pulverization apparatus, but in order to effectively perform trituration using a pulverizing medium (water-soluble inorganic salt), the operating conditions in a case in which the apparatus is a kneader are such that the speed of rotation of the blade in the apparatus is preferably from 10 rpm to 200 rpm. Furthermore, when the speed ratio of two screws is relatively larger, a high trituration effect is obtained, which is preferable. Also, the operation time is preferably from 1 hour to 8 hours including the dry pulverization time, and the internal temperature of the apparatus is preferably from 50° C. to 150° C. Regarding the water-soluble inorganic salt as a pulverizing medium, a pulverization particle size of from 5 μm to 50 μm, a sharp distribution of the particle size, and a spherical shape are preferred.

The mixture obtained after trituration such as described above is mixed with warm water at 80° C., the water-soluble organic solvent and the water-soluble inorganic salt are dissolved, and then the mixture is filtered, washed with water, and dried in an oven. Thus, a fine organic pigment can be obtained.

[Pigment Dispersion Composition]

When the colored composition according to the invention is formed, in a case in which the colored composition includes a yellow pigment or a green pigment, it is preferable that a pigment dispersion composition is prepared, and that this composition is used.

A pigment dispersion composition is formed by dispersing a pigment in a solvent together with a dispersant or a pigment derivative.

The dispersant used here is used in order to enhance dispersibility of the pigment, and for example, a known pigment dispersant or surfactant can be appropriately selected and used.

—Dispersant—

Regarding the dispersant, specifically, many kinds of compounds can be used, and examples include cationic surfactants such as organosiloxane polymer KP341 (manufactured by Shin-Etsu Chemical Co., Ltd.), (meth)acrylic acid-based (co)polymers POLYFLOW No. 75, No. 90 and No. 95 (manufactured by Kyoeisha Chemical Co., Ltd.), and W001 (manufactured by Yusho Co., Ltd.); nonionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid esters; anionic surfactants such as W004, W005, and W017 (manufactured by Yusho Co., Ltd.); polymeric dispersants such as EFKA-46, EFKA-47, EFKA-47EA, EFKA POLYMER 100, EFKA POLYMER 400, EFKA POLYMER 401, and EFKA POLYMER 450 (all manufactured by Ciba Specialty Chemical Corp.), DISPERSE AID 6, DISPERSE AID 8, DISPERSE AID 15, and DISPERSE AID 9100 (all manufactured by San Nopco, Ltd.); various SOLSPERSE dispersants such as SOLSPERSE 3000, 5000, 9000, 12000, 13240, 13940, 17000, 24000, 26000, and 28000 (manufactured by Lubrizol Japan, Ltd.); ADEKA PLURONIC L31, F38, L42, L44, L61, L64, F68, L72, P95, F77, P84, F87, P94, L101, P103, F108, L121, and P-123 (manufactured by Asahi Denka Co., Ltd.), ISONET S-20 (manufactured by Sanyo Chemical Industries, Ltd.), DISPERBYK-101, -103, -106, -108, -109, -111, -112, -116, -130, -140, -142, -161, -162, -163, -164, -166, -167, -170, -171, -174, -176, -180, -182, -2000, -2001, -2050, and -2150 (manufactured by BYK Chemie Japan K.K.). Other examples include oligomers or polymers having polar groups in the molecule ends or side chains, such as acrylic copolymers.

The amount of use of the dispersant is preferably from 0.5 parts by mass to 100 parts by mass, and more preferably from 3 parts by mass to 70 parts by mass, with respect to 100 parts by mass of the total amount of the pigments included in the pigment dispersion composition. When the amount of the dispersant is in this range, a sufficient pigment dispersing effect can be obtained. Meanwhile, even if the dispersant is added in an amount of more than 100 parts by mass, a further effect of the pigment dispersing effect may not be expected.

—Pigment Derivative—

The pigment dispersion composition may also include a pigment derivative as necessary.

According to the invention, when a pigment derivative in which a moiety having affinity with the aforementioned dispersant, or a polar group has been introduced, is adsorbed to the pigment surface, and this is used as an adsorption point for the dispersant, the pigment can be dispersed in the pigment dispersion composition as fine particles, and reaggregation thereof can also be prevented. That is, the pigment derivative has an effect of promoting adsorption of the dispersant by modifying the pigment surface.

Specifically, the pigment derivative used in the invention is a compound which has an organic pigment as a main skeleton, and has an acidic group, a basic group or an aromatic group introduced as a substituent in the side chain. Specific examples of the organic pigment that constitutes the main skeleton include a quinacridone-based pigment, a phthalocyanine-based pigment, an azo-based pigment, a quinophthalone-based pigment, an isoindoline-based pigment, an isoindolinone-based pigment, a quinoline pigment, and a benzimidazolone pigment. Generally, aromatic polycyclic compounds of pale yellow color, such as naphthalene-based, anthraquinone-based, triazine-based and quinoline-based compounds that are not called coloring materials, are also included.

Examples of the pigment derivative that can be used include those described in JP-A No. H11-49974, JP-A No. H11-189732, JP-A No. H10-245501, JP-A No. 2006-265528, JP-A No. H08-295810, JP-A No. H11-199796, JP-A No. 2005-234478, JP-A No. 2003-240938, JP-A No. 2001-356210, and the like.

The content of the pigment derivative related to the invention in the pigment dispersion composition is preferably from 1% by mass to 30% by mass, and more preferably from 3% by mass to 20% by mass, with respect to the mass of the pigments. When the content is in the range described above, dispersing can be carried out favorably while having the viscosity suppressed at a low level, and also, dispersion stability after being dispersed can be enhanced. Excellent color characteristics with high transmittance are thereby obtained, and when a color filter is produced, a color filter having favorable color characteristics and high contrast can be constituted.

—Solvent—

Examples of the solvent included in the pigment dispersion composition include the same solvents as those included in the colored photosensitive composition that will be described below.

The pigment concentration in the pigment dispersion composition is preferably from 30% by mass to 90% by mass, and more preferably from 40% by mass to 80% by mass.

The pigment dispersion composition according to the invention can be prepared by going through a mixing and dispersing step of performing mixing and dispersion using various mixing machines and dispersing machines.

The mixing and dispersing step preferably includes kneading dispersion, and a fine dispersion treatment that is carried out subsequently thereto. However, kneading dispersion can also be omitted.

Specifically, for example, a pigment dispersion composition can be prepared by mixing in advance a pigment and if necessary, a dispersant, further dispersing in advance the mixture with a homogenizer or the like, and finely dispersing the resultant using a bead dispersing machine (for example, DISPERMAT manufactured by VMA-Getzmann GmbH) that uses zirconia beads or the like.

In regard to the dispersing time, a time period of from 3 hours to 6 hours is suitable.

Furthermore, a fine dispersion treatment using beads can be carried out using mainly a vertical type or horizontal type sand grinder, a pin mill, a slit mill, an ultrasonic dispersing machine or the like, and using beads formed of glass, zirconia or the like having a particle size of from 0.01 mm to 1 mm.

The details of the kneading and dispersing processes are described in T. C. Patton, “Paint Flow and Pigment Dispersion” (1964, published by John Wiley and Sons, Inc.) and the like.

[Solvent]

The colored composition used in the invention can be prepared suitably using, in general, a solvent together with the components described above.

Examples of the solvent include esters, for example, ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, ethyl ethoxyacetate, and 3-oxypropionic acid alkyl esters such as methyl 3-oxypropionate and ethyl 3-oxypropionate; methyl 3-methoxypropionate, ethyl 3-methoxypropionate, methyl 3-ethoxypropionate, ethyl 3-ethoxypropionate, methyl 2-oxypropionate, ethyl 2-oxypropionate, propyl 2-oxypropionate, methyl 2-methoxypropionate, ethyl 2-methoxypropionate, propyl 2-methoxypropionate, methyl 2-ethoxypropinoate, ethyl 2-ethoxypropionate, methyl 2-oxy-2-methylpropionate, ethyl 2-oxy-2-methylpropionate, methyl 2-methoxy-2-methylpropionate, ethyl 2-oxy-2-methylpropionate, methyl 2-methoxy-2-methylpropionate, ethyl 2-ethoxy-2-methylpropionate, methyl pyruvate, ethyl pyruvate, propyl pyruvate, methyl acetoacetate, ethyl acetoacetate, methyl 2-oxobutanoate, and ethyl 2-oxobutanoate; ethers, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol methyl ether acetate, propylene glycol ethyl ether acetate, propylene glycol propyl ether acetate, and cyclohexyl acetate; ketones, for example, methyl ethyl ketone, cyclohexanone, 2-heptanone, and 3-heptanone; and aromatic hydrocarbons, for example, toluene and xylene.

Among these, methyl 3-ethoxypropionate, ethyl 3-ethoxypropionate, ethyl cellosolve acetate, ethyl lactate, diethylene glycol dimethyl ether, butyl acetate, butyl methoxyacetate, methyl 3-methoxypropionate, 2-heptanone, cyclohexanone, cyclohexyl acetate, ethyl carbitol acetate, butyl carbitol acetate, propylene glycol methyl ether acetate, and the like are suitable.

The solvents may be used singly or in combination of two or more kinds thereof.

[Colored Composition]

The colored composition of the invention is prepared by mixing the various components described above, and optional components as necessary.

On the occasion of the preparation of the colored composition, various components may be blended all at once, or various components may be dissolved or dispersed in solvents, and then blended in sequence. Furthermore, there are no particular limitations on the order of input or operating conditions at the time of blending. For example, a composition may be prepared by dissolving or dispersing all the components at the same time, or if necessary, various components may be appropriately prepared into two or more solutions/dispersion liquids, and a composition may be prepared by mixing these at the time of use.

However, when a pigment is used as a component, it is preferable to disperse the pigment in advance, and to prepare a colored composition from the pigment dispersion liquid.

The colored composition prepared as described above can be provided for use after being filtered using a filter having a pore diameter of about from 0.01 μm to 3.0 μm, and more preferably a pore diameter of about from 0.05 μm to 1.0 μm, or the like.

[Colored Photosensitive Composition]

For the colored photosensitive composition according to the invention, it is preferable to use the colored composition described above.

The content of a coloring material in the colored photosensitive composition is preferably from 30% by mass to 60% by mass, more preferably from 35% by mass to 60% by mass, and still more preferably from 40% by mass to 60% by mass, with respect to the total solid content of the colored photosensitive composition.

When the concentration of the coloring material is in the range described above, it is effective for securing excellent color characteristics with a sufficient color density.

When a pigment derivative is used in the pigment dispersion composition, a pigment concentration including the amount of pigment derivatives is used.

The colored photosensitive composition used in the invention preferably includes an alkali-soluble binder, a polymerizable compound, a photopolymerization initiator, a solvent and the like, in addition to the colored composition.

The various components that constitute the colored photosensitive composition will be described below.

(Alkali-Soluble Binder)

The alkali-soluble binder is not particularly limited except for the property of having alkali-solubility, and preferably, the alkali-soluble binder can be selected from the viewpoints of heat resistance, develop ability, availability and the like.

As the alkali-soluble binder, a linear organic high molecular weight polymer which is soluble in organic solvents and can be developed with an aqueous weak alkali solution is preferred. Examples of such a linear organic high molecular weight polymer include polymers having a carboxylic acid in side chains, for example, the methacrylic acid copolymers, acrylic acid copolymers, itaconic acid copolymers, crotonic acid copolymers, maleic acid copolymers, and partially esterified maleic acid copolymers described in JP-A No. S59-44615, Japanese Patent Publication (JP-B) No. S54-34327, JP-B No. S58-12577, JP-B No. S54-25957, JP-A No. S59-53836, and JP-A No. S59-71048. Similarly, acidic cellulose derivatives having a carboxylic acid in side chains are useful.

In addition to those described above, regarding the alkali-soluble binder according to the invention, a compound obtained by adding an acid anhydride to a polymer having hydroxyl groups, a polyhydroxystyrene-based resin, a polysiloxane-based resin, a poly(2-hydroxyethyl(meth)acrylate), polyvinylpyrrolidone, polyethylene oxide, polyvinyl alcohol and the like are also useful. Furthermore, the linear organic high molecular weight polymer may be a product obtained by copolymerizing hydrophilic monomers. Examples thereof include alkoxyalkyl(meth)acrylate, hydroxyalkyl(meth)acrylate, glycerol (meth)acrylate, (meth)acrylamide, N-methylol acrylamide, secondary or tertiary alkyl acrylamide, dialkyl aminoalkyl(meth)acrylate, morpholine(meth)acrylate, N-vinylpyrrolidone, N-vinylcaprolactam, vinylimidazole, vinyltriazole, methyl(meth)acrylate, ethyl(meth)acrylate, branched or linear propyl(meth)acrylate, branched or linear butyl(meth)acrylate, and phenoxyhydroxypropyl(meth)acrylate. Other examples of the hydrophilic monomers that are also useful include monomers having a tetrahydrofurfuryl group, a phosphoric acid group, a phosphoric acid ester group, a quaternary ammonium salt group, an ethyleneoxy chain, a propyleneoxy chain, a sulfonic acid group and a group derived from a salt thereof, a morpholinoethyl group and the like.

Furthermore, the alkali-soluble binder may also have a polymerizable group in side chains in order to increase the crosslinking efficiency, and for example, polymers containing an allyl group, a (meth)acryl group, an allyloxyalkyl group and the like in the side chains are also useful. Regarding the alkali-soluble binder having a polymerizable group, alkali-soluble resins containing an allyl group, a (meth)acryl group, an allyloxyalkyl group, and the like in the side chains are useful. Examples of the alkali-soluble binder containing the aforementioned polymerizable groups include DIANAL NR Series (manufactured by Mitsubishi Rayon Co., Ltd.), PHOTOMER 6173 (polyurethane acrylic oligomer containing COOH, manufactured by Diamond Shamrock Co., Ltd.), VISCOAT R-264 and KS RESIST 106 (all manufactured by Osaka Organic Chemical Industry, Ltd.), CYCLOMER P Series and PLACCEL CF200 Series (all manufactured by Daicel Corporation), and EBECRYL 3800 (manufactured by Daicel-UCB Co., Ltd.).

Furthermore, in order to increase the strength of the cured coating film, an alcohol-soluble nylon, a polyether of 2,2-bis(4-hydroxyphenyl)propane and epichlorohydrin, and the like are also useful.

Among these various alkali-soluble binders, a polyhydroxystyrene-based resin, a polysiloxane-based resin, an acrylic resin, an acrylamide-based resin, and an acryl/acrylamide copolymer resin are preferred from the viewpoint of heat resistance, and from the viewpoint of controlling developability, an acrylic resin, an acrylamide-based resin, and an acryl/acrylamide copolymer resin are preferred.

Regarding the acrylic resin, copolymers formed from monomers selected from benzyl(meth)acrylate, (meth)acrylic acid, hydroxyethyl(meth)acrylate, (meth)acrylamide and the like, or commercially available products such as KS RESIST-106 (manufactured by Osaka Organic Chemical Industry, Ltd.) and CYCLOMER P Series (manufactured by Daicel Corp.) are preferred.

The alkali-soluble binder is preferably a polymer having a weight average molecular weight (a value measured by a GPC method and calculated relative to polystyrene standards) of 1000 to 2×10⁵, more preferably a polymer having a weight average molecular weight of 2000 to 1×10⁵, and particularly preferably a polymer having a weight average molecular weight of 5000 to 5×10⁴, from the viewpoints of developability, liquid viscosity and the like.

(Polymerizable Compound)

The colored photosensitive composition of the invention includes at least one polymerizable compound. An example of the polymerizable compound may be an addition polymerizable compound having at least one ethylenically unsaturated double bond.

Specifically, the polymerizable compound is selected from compounds having at least one, and preferably two or more, terminal ethylenically unsaturated bonds. The group of such compounds is compounds widely known in the relevant industrial field, and these can be used without any particular limitations in this invention. These may be, for example, any of chemical forms such as a monomer, a prepolymer, that is, a dimer, a trimer, or an oligomer, a mixture thereof, and a (co)polymer thereof.

Examples of monomers and (co)polymers thereof include unsaturated carboxylic acids (for example, acrylic acid, methacrylic acid, itaconic acid, crotonic acid, isocrotonic acid, and maleic acid) or esters thereof; amides; and (co)polymers thereof, and preferred examples include esters between unsaturated carboxylic acids and aliphatic polyhydric alcohol compounds, amides between unsaturated carboxylic acids and aliphatic polyvalent amine compounds, and (co)polymers thereof. Furthermore, an addition reaction product between an unsaturated carboxylic acid ester or an amide, each having a nucleophilic substituent such as a hydroxyl group, an amino group or a mercapto group, and a monofunctional or polyfunctional isocyanate or epoxy; a dehydration condensation reaction product with a monofunctional or polyfunctional carboxylic acid; and the like are also suitably used. Also, an addition reaction product between an unsaturated carboxylic acid ester or amide having an electrophilic substituent such as an isocyanate group or an epoxy group, and a monofunctional or polyfunctional alcohol, amine, or thiol; and a substitution reaction product between an unsaturated carboxylic acid ester or amide having a leaving substituent group such as a halogen group or a tosyloxy group, and a monofunctional or polyfunctional alcohol, amine or thiol, are also suitable. As other examples, a group of compounds obtained by substituting the unsaturated carboxylic acid with an unsaturated phosphonic acid, styrene, a vinyl ether or the like can also be used.

Specific examples of the monomer of an ester of an aliphatic polyhydric alcohol compound and an unsaturated carboxylic acid include, as acrylic acid esters, for example, ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl) ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl) isocyanurate, polyester acrylate oligomer, and isocyanuric acid EO-modified triacrylate.

Furthermore, examples of methacrylic acid esters include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, and bis[p-(methacryloxyethoxy)phenyl]dimethylmethane.

Examples of itaconic acid esters include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate; examples of crotonic acid esters include ethylene glycol dicrotonate, tetramethylene glycol dicrotonate, pentaerythritol dicrotonate, and sorbitol tetradicrotonate; examples of isocrotonic acid esters include ethylene glycol diisocrotonate, pentaerythritol diisocrotonate, and sorbitol tetraisocrotonate; and examples of maleic acid esters include ethylene glycol dimaleate, triethylene glycol dimaleate, pentaerythritol dimaleate, and sorbitol tetramaleate.

Other examples of esters that can be suitably used include the aliphatic alcohol-based esters described in JP-B No. S51-47334, JP-A No. S57-196231; the esters having an aromatic-based skeleton as described in JP-A No. S59-5240, JP-A No. S59-5241, and JP-A No. H02-226149; and the esters containing amino groups as described in JP-A No. H01-165613. Furthermore, the ester monomers described above can also be used in mixture.

Specific examples of monomers of amides between aliphatic polyvalent amine compounds and unsaturated carboxylic acids include methylenebisacrylamide, methylenebismethacrylamide, 1,6-hexamethylenebisacrylamide, 1,6-hexamethylenebismethacrylamide, diethylenetriamine trisacrylamide, xylylene bisacrylamide, and xylylene bismethacrylamide.

Other preferred examples of amide-based monomers include the monomers having a cyclohexylene structure described in JP-B No. S54-21726.

Furthermore, urethane-based addition polymerizable compounds produced using an addition reaction between an isocyanate and a hydroxyl group are also suitable, and specific examples thereof include a vinylurethane compound containing two or more polymerizable vinyl groups in one molecule, obtained by adding a vinyl monomer containing a hydroxyl group represented by the following Formula, to a polyisocyanate compound having two or more isocyanate groups in one molecule, as described in JP-B No. S48-41708.

CH₂═C(R)COOCH₂CH(R′)OH

wherein each of R and R′ independently represents H or CH₃.

In regard to these polymerizable compounds, the structures thereof, and the details of the method of use regarding the question of whether the compounds are used singly or in combination, and the amount of addition, can be arbitrarily set up in accordance with the final performance design of the colored photosensitive composition. For example, from the viewpoint of sensitivity, a structure having a large content of unsaturated groups in one molecule is preferred, and in many cases, bifunctionality or higher functionality is preferred. Furthermore, from the viewpoint of increasing the strength of the photosensitive colored cured film, trifunctionality or higher functionality is preferred, and a method of regulating both sensitivity and strength by using polymerizable compounds having different functionalities and different polymerizable groups (for example, acrylic acid esters, methacrylic acid esters, styrene-based compounds, and vinyl ether-based compounds) in combination, is also effective. Furthermore, selection of the polymerizable compounds and the method of use are also important factors in connection with compatibility with other components that are included in the colored photosensitive composition (for example, a photopolymerization initiator, a colorant (a dye or a pigment), and a binder polymer) and with dispersibility, and for example, compatibility may be enhanced by using a low purity compound, or by using two or more kinds in combination. Furthermore, a particular structure may also be selected from the viewpoint of enhancing adhesiveness to hard surfaces of a support or the like.

The content of the polymerizable compound (in the case of using two or more kinds, total content) in the total solid content of the colored photosensitive composition is not particularly limited, and from the viewpoint of obtaining the effects of the invention more effectively, the content is preferably from 10% by mass to 80% by mass, more preferably from 15% by mass to 75% by mass, and particularly preferably from 20% by mass to 60% by mass.

(Photopolymerization Initiator)

The colored photosensitive composition of the invention preferably includes at least one photopolymerization initiator. The photopolymerization initiator is not particularly limited as long as the initiator is capable of polymerizing the polymerizable compound, and the photopolymerization initiator is preferably selected from the viewpoints of characteristics, initiation efficiency, absorption wavelength, availability, cost and the like.

Examples of the photopolymerization initiator include at least one active halogen compound selected from a halomethyloxadiazole compound and a halomethyl-s-triazine compound; a 3-aryl-substituted coumarin compound, a biimidazole compound, a benzophenone compound, an acetophenone compound and derivatives thereof, a cyclopentadiene-benzene-iron complex and salts thereof, and an oxime-based compound. Specific examples of the photopolymerization initiator include the compounds described in paragraphs [0070] to [0077] of JP-A No. 2004-295116. Among them, an oxime-based compound and a biimidazole compound are preferred from the viewpoint that the polymerization reaction occurs rapidly.

There are no particular limitations on the oxime-based compound (hereinafter, also referred to as “oxime-based photopolymerization initiator”), and examples include the oxime-based compounds described in JP-A No. 2000-80068, WO 02/100903 A1, and JP-A No. 2001-233842.

Specific examples include 2-(O-benzoyloxime)-1-[4-(phenylthio)phenyl]-1,2-butanedione, 2-(O-benzoyloxime)-1-[4-(phenylthio)phenyl]-1,2-pentanedione, 2-(O-benzoyloxime)-1-[4-(phenylthio)phenyl]-1,2-hexanedione, 2-(O-benzoyloxime)-1-[4-(phenylthio)phenyl]-1,2-heptanedione, 2-(O-benzoyloxime)-1-[4-(phenylthio)phenyl]-1,2-octanedione, 2-(O-benzoyloxime)-1-[4-(methylphenylthio)phenyl]-1,2-butanedione, 2-(O-benzoyloxime)-1-[4-(ethylphenylthio)phenyl]-1,2-butanedione, 2-(O-benzoyloxime)-1-[4-(butylphenylthio)phenyl]-1,2-butanedione, 1-(O-acetyloxime)-1-[9-ethyl-6-(2-methylbenzoyl)-9H-carbazol-3-yl]ethanone, 1-(O-acetyloxime)-1-[9-methyl-6-(2-methylbenzoyl)-9H-carbazol-3-yl]ethanone, 1-(O-acetyloxime)-1-[9-propyl-6-(2-methylbenzoyl)-9H-carbazol-3-yl]ethanone, 1-(O-acetyloxime)-1-[9-ethyl-6-(2-ethylbenzoyl)-9H-carbazol-3-yl]ethanone, and 1-(O-acetyloxime)-1-[9-ethyl-6-(2-butylbenzoyl)-9H-carbazol-3-yl]ethanone. However, the compounds are not intended to be limited to these.

Furthermore, according to the invention, a compound represented by the following Formula (1) is more preferred as an oxime-based compound, from the viewpoints of sensitivity, stability over time, and post-heating coloration.

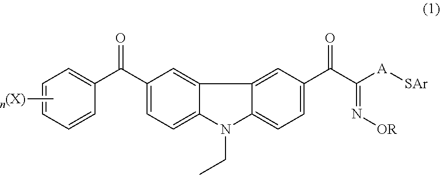

In the above Formula (1), each of R and X independently represents a monovalent substituent; A represents a divalent organic group; Ar represents an aryl group; and n represents an integer from 0 to 5.

R is preferably an acyl group from the viewpoint of increasing sensitivity, and specific preferred examples include an acetyl group, a propionyl group, a benzoyl group, and a toluyl group.

A is preferably an unsubstituted alkylene group, an alkylene group substituted with an alkyl group (for example, a methyl group, an ethyl group, a tert-butyl group, or a dodecyl group), an alkylene group substituted with an alkenyl group (for example, a vinyl group or an allyl group), or an alkylene group substituted with an aryl group (for example, a phenyl group, a p-tolyl group, a xylyl group, a cumenyl group, a naphthyl group, an anthryl group, a phenanthryl group, or a styryl group), from the viewpoint of increasing sensitivity and suppressing coloration caused by heating or passage of time.

Ar is preferably a substituted or unsubstituted phenyl group, from the viewpoint of increasing sensitivity and suppressing coloration caused by heating or passage of time. In the case of a substituted phenyl group, preferred examples of substituents thereof include halogen groups such as a fluorine atom, a chlorine atom, a bromine atom, and an iodine atom.

X is preferably an alkyl group which may have a substituent, an aryl group which may have a substituent, an alkenyl group which may have a substituent, an alkynyl group which may have a substituent, an alkoxy group which may have a substituent, an aryloxy group which may have a substituent, an alkylthioxy group which may have a substituent, an arylthioxy group which may have a substituent, or an amino group which may have a substituent, from the viewpoint of enhancing the solvent solubility and the absorption efficiency in the longer wavelength region.

Furthermore, n in Formula (1) is preferably an integer of 1 or 2.

Specific examples of hexaarylbisimidazole represented by Formula (I) will be described below.

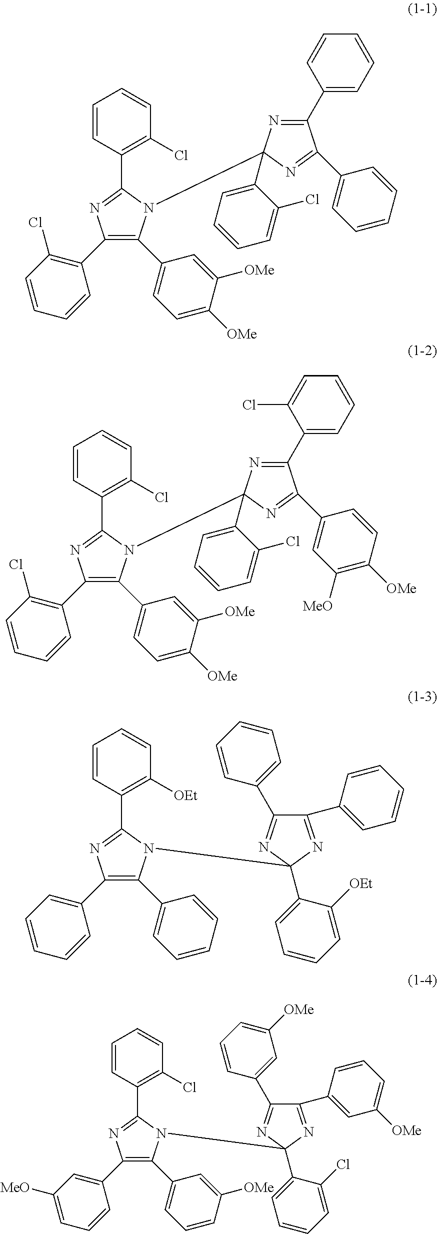 [SMILES: COc1ccc(-c2c(-c3ccccc3Cl)nc(-c3ccccc3Cl)n2C2(c3ccccc3Cl)N=C(c3ccccc3)C(c3ccccc3)=N2)cc1OC ; COc1ccc(C2=NC(c3ccccc3Cl)(n3c(-c4ccccc4Cl)nc(-c4ccccc4Cl)c3-c3ccc(OC)c(OC)c3)N=C2c2ccccc2Cl)cc1OC ; CCOc1ccccc1-c1nc(-c2ccccc2)c(-c2ccccc2)n1C1(c2ccccc2OCC)N=C(c2ccccc2)C(c2ccccc2)=N1 ; COc1cccc(C2=NC(c3ccccc3Cl)(n3c(-c4ccccc4Cl)nc(-c4cccc(OC)c4)c3-c3cccc(OC)c3)N=C2c2cccc(OC)c2)c1]

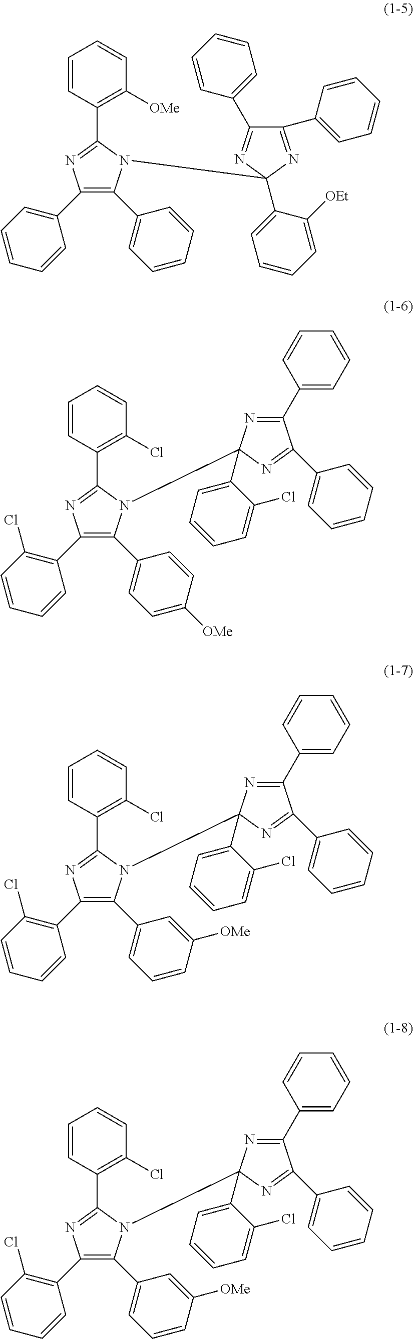 [SMILES: CCOc1ccccc1C1(n2c(-c3ccccc3OC)nc(-c3ccccc3)c2-c2ccccc2)N=C(c2ccccc2)C(c2ccccc2)=N1 ; COc1ccc(-c2c(-c3ccccc3Cl)nc(-c3ccccc3Cl)n2C2(c3ccccc3Cl)N=C(c3ccccc3)C(c3ccccc3)=N2)cc1 ; COc1cccc(-c2c(-c3ccccc3Cl)nc(-c3ccccc3Cl)n2C2(c3ccccc3Cl)N=C(c3ccccc3)C(c3ccccc3)=N2)c1 ; COc1cccc(-c2c(-c3ccccc3Cl)nc(-c3ccccc3Cl)n2C2(c3ccccc3Cl)N=C(c3ccccc3)C(c3ccccc3)=N2)c1]

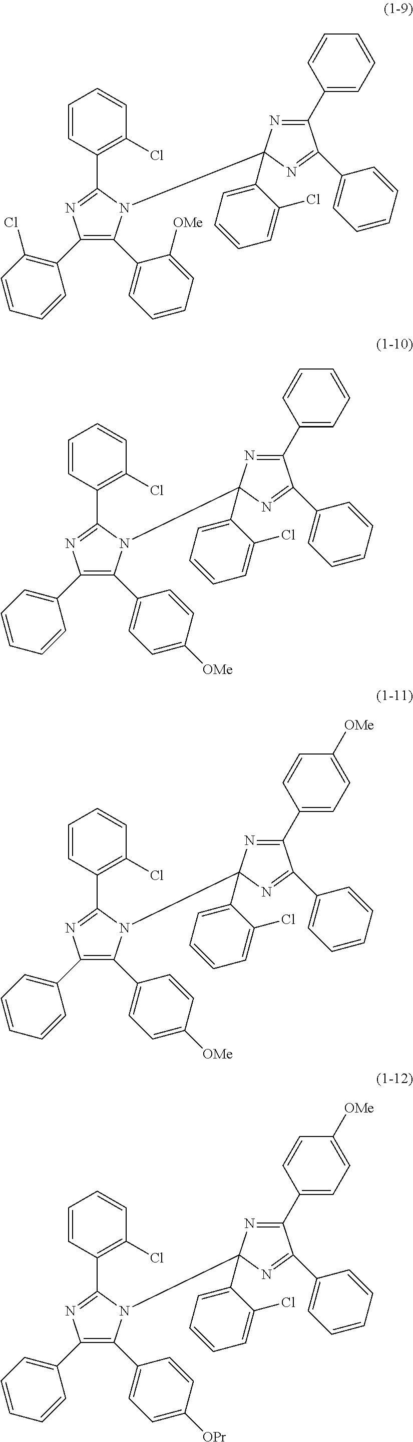

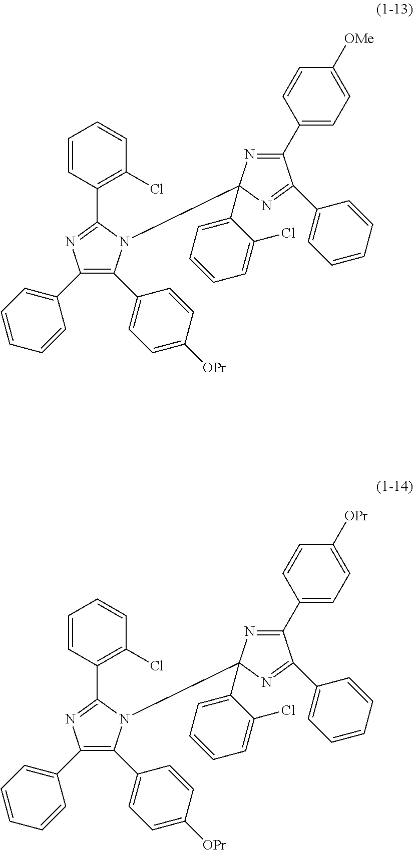

Among these, compounds (I-1), (I-2), (I-4) and (I-11) are preferred from the viewpoints of solubility in solvents, reactivity, and transparency.

Suitable examples of the acetophenone-based photopolymerization initiator include 2,2-diethoxyacetophenone, p-dimethylaminoacetophenone, 2-hydroxy-2-methyl-1-phenylpropan-1-one, p-dimethylaminoacetophenone, and 4′-isopropyl-2-hydroxy-2-methylpropiophenone.

Suitable examples of the benzophenone-based photopolymerization initiator include benzophenone, 4,4′-(bisdimethylamino)benzophenone, 4,4′-(bisdiethylamino)benzophenone, 4,4′-dichlorobenzophenone, 1-hydroxycyclohexyl phenyl ketone, 2-benzyl-2-dimethylamino-1-(4-morpholinophenyl)butanone-1, 2-tolyl-2-dimethylamino-1-(4-morpholinophenyl)butanone-1, and 2-methyl-1-[4-(methylthio)phenyl]-2-morpholinopropanone-1.

Suitable examples of the triazine-based photopolymerization initiator include 2,4-bis(trichloromethyl)-6-p-methoxyphenyl-s-triazine, 2,4-bis(trichloromethyl)-6-p-methoxystyryl-s-triazine, 2,4-bis(trichloromethyl)-6-(1-p-dimethylaminophenyl)-1,3-butadienyl-s-triazine, 2,4-bis(trichloromethyl)-6-biphenyl-s-triazine, 2,4-bis(trichloromethyl)-6-(p-methylbiphenyl)-s-triazine, p-hydroxyethoxystyryl-2,6-di(trichloromethyl)-s-triazine, methoxystyryl-2,6-di(trichloromethyl)-s-triazine, 3,4-dimethoxystyryl-2,6-di(trichloromethyl)-s-triazine, 4-benzoxolane-2,6-di(trichloromethyl)-s-triazine, 4-(o-bromo-p-N,N-(diethoxycarbonylamino)phenyl)-2,6-di(chloromethyl)-s-triazine, and 4-(p-N,N-(diethoxycarbonylamino)phenyl)-2,6-di(chloromethyl)-s-triazine.

Suitable examples of the halomethyloxadiazole-based photopolymerization initiator include 2-trichloromethyl-5-styryl-1,3,4-oxadiazole, 2-trichloromethyl-5-(cyanostyryl)-1,3,4-oxadiazole, 2-trichloromethyl-5-(naphth-1-yl)-1,3,4-oxadiazole, and 2-trichloromethyl-5-(4-styryl)styryl-1,3,4-oxadiazole.

Suitable examples of the coumarin-based photopolymerization initiator include 3-methyl-5-amino-((s-triazin-2-yl)amino)-3-phenylcoumarin, 3-chloro-5-diethylamino-((s-triazin-2-yl)amino)-3-phenylcoumarin, and 3-butyl-5-dimethylamino-((s-triazin-2-yl)amino)-3-phenylcoumarin.

In addition to the compounds described above, further examples of the photopolymerization initiator according to the invention include 1-phenyl-1,2-propanedione-2-(o-ethoxycarbonyl)oxime, o-benzoyl-4′-(benzomercapto)benzoyl-hexyl-ketoxime, 2,4,6-trimethylphenylcarbonyl diphenyl phosphonyl oxide, and hexafluorophosphorotrialkylphenylphosphonium salt.

In this invention, the photopolymerization initiator is not intended to be limited to the above initiators, and other known compounds can also be used. Examples include the vicinal polyketaldonyl compound described in U.S. Pat. No. 2,367,660; the a-carbonyl compound described in US Patent Nos. 2,367,661 and 2, 367,670; the acyloin ether described in U.S. Pat. No. 2,448,828; the aromatic acyloin compound substituted with an a-hydrocarbon described in U.S. Pat. No. 2,722,512; the polynuclear quinone compounds described in U.S. Pat. Nos. 3,046,127 and 2,951,758; the combination of triallylimidazole dimer/p-aminophenyl ketone described in U.S. Pat. No. 3,549,367; the benzothiazole-based compound/trihalomethyl-s-triazine-based compound described in JP-B No. S51-48516; and the oxime ester compounds described in J. C. S. Perkin II (1979) 1653-1660, J. C. S. Perkin II (1979) 156-162, Journal of Photopolymer Science and Technology (1995) 202-232, and JP-A No. 2000-66385.

These photopolymerization initiators can be used in combination.

The photopolymerization initiators can be incorporated singly or in combination of two or more kinds

The content of the photopolymerization initiator (in the case of using two or more kinds, the total content) in the total solid content of the colored photosensitive composition is preferably from 3% by mass to 20% by mass, more preferably from 4% by mass to 19% by mass, and particularly preferably from 5% by mass to 18% by mass, from the viewpoint of obtaining the effects of the invention more effectively.

The colored photosensitive composition used in the invention may include, if necessary, a sensitizer, a hydrogen donating compound, a fluorine-containing organic compound, a thermal polymerization initiator, a thermal polymerizable component, a thermal polymerization inhibitor, as well as various additives such as a filler, a polymer compound other than the alkali-soluble resin (binder polymer) described above, a surfactant, an adhesion promoting agent, an oxidation inhibitor, an ultraviolet absorber, and an aggregation preventing agent.

(Sensitizer)

It is preferable that a sensitizer is further added to the colored photosensitive composition of the invention, from the viewpoint of increasing sensitivity. A radical generating reaction of the photopolymerization initiator component, or a polymerization reaction of the ethylenically unsaturated compound caused thereby is promoted by exposure to the wavelength that can be absorbed by this sensitizer.

Examples of such a sensitizer include known spectral sensitizer, known dyes, and dyes or pigments that absorb light and interact with photopolymerization initiators.

Preferred examples of the sensitizer that can be used in the invention include spectral sensitizing coloring materials or dyes exemplified in the following.

Examples include the styryl-based coloring material described in JP-B H37-13034; the cationic dye described in JP-A No. S62-143044; the quinoxalinium salt described in JP-B No. S59-24147; the new Methylene Blue compound described in JP-A No. S64-33104; the anthraquinones described in JP-A No. S64-56767; the benzoxanthene dye described in JP-A No. H02-1714; the acridines described in JP-A No. H02-226148 and JP-A No. H02-226149; the pyrylium salts described in JP-B No. S40-28499; the cyanines described in JP-B No. S46-42363; the benzofuran coloring material described in JP-A No. H02-63053; the conjugated ketone coloring materials described in JP-A No. H02-85858 and JP-A No. H02-216154; the coloring material described in JP-A No. S57-10605; the azocinnamylidene derivative described in JP-B H02-30321; the cyanine-based dye described in JP-A H01-287105; the xanthene-based dyes described in JP-A No. S62-31844, JP-A No. S62-31848, and JP-A No. S62-143043; the aminostyryl ketone described in JP-B No. S59-28325; the coloring material described in JP-A No. H02-179643; the merocyanine coloring dye described in JP-A No. H02-244050; the merocyanine coloring material described in JP-B No. S59-28326; the merocyanine coloring material described in JP-A No. S59-89303; the merocyanine coloring material described in JP-A No. H08-129257; and the benzopyran-based coloring material described in JP-A No. H08-334897.

Other preferred embodiments of the sensitizing dye include dyes that belong to the following compound group and have a maximum absorption wavelength of 350 nm to 450 nm.

Examples include polynuclear aromatic compounds (for example, pyrene, perylene, and triphenylene), xanthenes (for example, fluorescein, eosin, erythrosine, rhodamine B, Rose Bengal), cyanines (for example, thiacarbocyanine and oxacarbocyanine), merocyanines (for example, merocyanine and carbomerocyanine), thiazines (for example, thionine, Methylene Blue, and Toluidine Blue), acridines (for example, Acridine Orange, chloroflavin, and acriflavin), anthraquinones (for example, anthraquinone), and squaryliums (for example, squarylium).

The content of the sensitizer is preferably, on a mass basis, 0.01% by mass or more but less than 5% by mass, more preferably 0.1% by mass or more but less than 5% by mass, and particularly preferably from 0.3% by mass to 2% by mass, with respect to the total solid content of the colored photosensitive composition. When the content is in this range, a colored photosensitive composition that exhibits no coloration and has high sensitivity and favorable pattern formability can be obtained.

—Hydrogen Donating Compound—

The colored photosensitive composition used in the invention preferably includes a hydrogen donating compound. The hydrogen donating compound according to the invention has an action of further enhancing the sensitivity of a sensitizing coloring material or a photopolymerization initiator to active radiation, or suppressing polymerization inhibition of a polymerizable compound by oxygen.

Examples of such a hydrogen donating compound include amines, for example, the compounds described in M. R. Sander, et al., “Journal of Polymer Society”, Vol. 10, p. 3173 (1972); JP-B No. S44-20189, JP-A No. S51-82102, JP-A No. S52-134692, JP-A No. S59-138205, JP-A No. S60-84305, JP-A No. S62-18537, JP-A No. S64-33104; and Research Disclosure No. 33825. Specific examples include triethanolamine, p-dimethylaminobenzoic acid ethyl ester, p-formyldimethylaniline, and p-methylthiodimethylaniline.

Other examples of the hydrogen donating compound include thiols and sulfides, for example, the thiol compounds described in JP-A No. S53-702, JP-B No. S55-500806, and JP-A No. H05-142772; and the disulfide compounds described in JP-A No. S56-75643. Specific examples include 2-mercaptobenzothiazole, 2-mercaptobenzoxazole, 2-mercaptobenzimidazole, 2-mercapto-4(3H)-quinazoline, β-mercaptonaphthalene, ethylene glycol bis(3-mercaptobutyrate), 1,2-propylene glycol bis(3-mercaptobutyrate), ethylene glycol bis(2-mercaptoisobutyrate), and 1,2-propylene glycol bis(2-mercaptoisobutyrate).

Still other examples of the hydrogen donating compound include amino acid compounds (for example, N-phenylglycine), the organometallic compounds (for example, tributyltin acetate) described in JP-B No. S48-42965, the hydrogen donors described in JP-B No. S55-34414, and the sulfur compounds (for example, trithiane) described in JP-A No. H06-308727.

The content of these hydrogen donating compounds is preferably in the range of from 0.1% by mass to 30% by mass, more preferably in the range of from 1% by mass to 25% by mass, and still more preferably in the range of from 0.5% by mass to 20% by mass, with respect to the mass of the total solid content of the colored photosensitive composition, from the viewpoint of increasing the rate of curing by the balance between the rate of polymerization growth and the chain transfer.

—Fluorine-Containing Organic Compound—

The colored photosensitive composition used in the invention may include a fluorine-containing organic compound.

When the composition includes this fluorine-containing organic compound, liquid characteristics (particularly, fluidity) on the occasion of using the colored photosensitive composition used in the invention as a coating liquid, can be improved, and uniformity of coating thickness or liquid saving performance can be improved. That is, when the interface tension between the surface to be coated and the coating liquid is decreased, wettability of the surface to be coated is improved, and coatability on the surface to be coated is enhanced. Therefore, it is effective from the viewpoint that even in a case in which a thin film having a thickness of about several micrometers (μm) is formed with a small amount of liquid, a film having a uniform thickness with less unevenness in thickness can be formed.

The fluorine content in the fluorine-containing organic compound is suitably from 3% by mass to 40% by mass, more preferably from 5% by mass to 30% by mass, and particularly preferably from 7% by mass to 25% by mass. When the fluorine percentage content is in the range described above, it is effective in view of uniformity of coating thickness or liquid saving performance, and also, favorable solubility in the composition is obtained.

Examples of the fluorine-containing organic compound include MEGAFACE F171, MEGAFACE F172, MEGAFACE F173, MEGAFACE F177, MEGAFACE F141, MEGAFACE F142, MEGAFACE F143, MEGAFACE F144, MEGAFACE R30, MEGAFACE F437 (all manufactured by DIC Corp.), FLUORAD FC430, FLUORAD FC431, FLUORAD FC171 (all manufactured by Sumitomo 3M, Ltd.), SURFLON S-382, SURFLON SC-101, SURFLON SC-103, SURFLON SC-104, SURFLON SC-105, SURFLON SC-1068, SURFLON SC-381, SURFLON SC-383, SURFLON 5393, and SURFLON KH-40 (all manufactured by Asahi Glass Co., Ltd.).

The fluorine-containing organic compound is, as described above, particularly effective in preventing coating unevenness or thickness unevenness when a thin coating film is produced. The fluorine-containing organic compound is also effective when the composition is applied to slit coating, which is prone to cause liquid shortage.

The amount of addition of the fluorine-containing organic compound is preferably from 0.001% by mass to 2.0% by mass, and more preferably from 0.005% by mass to 1.0% by mass, with respective to the total mass of the colored photosensitive composition.

—Thermal Polymerization Initiator—

In regard to the colored photosensitive composition used in the invention, it is also effective to incorporate the thermal polymerization initiator. Examples of the thermal polymerization initiator include various azo-based compounds and peroxide-based compounds. Examples of the azo-based compounds include azobis-based compounds, and examples of the peroxide-based compounds include ketone peroxide, peroxy ketal, hydroperoxides, dialkyl peroxides, diacyl peroxides, peroxy esters, and peroxy dicarbonates.

—Thermal Polymerizable Component—

It is also effective that the colored photosensitive composition used in the invention includes a thermal polymerizable component in order to increase the strength of the coating film. Preferred examples of the thermal polymerizable component include epoxy compounds.

An epoxy compound is a compound having two or more epoxy rings in a molecule, such as bisphenol A type, cresol-novolac type and biphenyl type compounds, and alicyclic epoxy compounds.

Examples of the bisphenol A type compounds include EPOTOTE YD-115, YD-118T, YD-127, YD-128, YD-134, YD-8125, YD-7011R, ZX-1059, YDF-8170, and YDF-170 (all manufactured by Tohto Chemical Industry Co., Ltd.); DENACOL EX-1101, EX-1102, and EX-1103 (all manufactured by Nagase & Co., Ltd.); PLACCEL GL-61, GL-62, G101 and G102 (all manufactured by Daicel Corp.), as well as bisphenol F type and bisphenol S type similar to these. Furthermore, epoxy acrylates such as EBECRYL 3700, 3701 and 600 (all manufactured by Daicel-UCB Co., Ltd.) can also be used.

Examples of the cresol-novolac type compounds include EPOTOTE YDPN-638, YDPN-701, YDPN-702, YDPN-703, and YDPN-704 (all manufactured by Tohto Chemical Industry Co., Ltd.); and DENACOL EM-125 (all manufactured by Nagase & Co., Ltd.). Examples of the biphenyl type compounds include 3,5,3′,5′-tetramethyl-4,4′-diglycidylbiphenyl, and examples of the alicyclic epoxy compounds include CELLOXIDE 2021, 2081, 2083 and 2085; EPOLIDE GT-301, GT-302, GT-401 and GT-403; EHPE-3150 (all manufactured by Daicel Corp.); and SANTOTO ST-3000, ST-4000, ST-5080, and ST-5100 (all manufactured by Tohto Chemical Industry Co., Ltd.). Furthermore, 1,1,2,2-tetrakis(p-glycidyloxyphenyl)ethane, tris(p-glycidyloxyphenyl)methane, triglycidyltris(hydroxyethyl) isocyanurate, o-phthalic acid diglycidyl ester, terephthalic acid diglycidyl ester, as well as EPOTOTE YH-434 and YH-434L, which are amine type epoxy resins, and a glycidyl ester obtained by modifying a dimeric acid in the skeleton of a bisphenol A type epoxy resin, can also be used.

—Surfactant—

It is preferable that the colored photosensitive composition used in the invention is configured using various surfactants, from the viewpoint of ameliorating coatability, and various nonionic, cationic and anionic surfactants can be used. Among them, fluorine-containing surfactants having perfluoroalkyl groups as nonionic surfactants are preferred.

Specific examples of the fluorine-containing surfactants include MEGAFACE (registered trademark) series manufactured by DIC Corp., and FLUORAD (registered trademark) series manufactured by 3M Co.

Furthermore, phthalocyanine derivatives (commercially available product: EFKA-745 (manufactured by Morishita Kagaku Sangyo Corp.)); cationic surfactants such as organosiloxane polymer KP341 (manufactured by Shin-Etsu Chemical Co., Ltd.), (meth)acrylic acid-based (co)polymers POLYFLOW No. 75, No. 90, and No. 95 (manufactured by Kyoeisha Yushi Kagaku Kogyo Co., Ltd.), and W001 (manufactured by Yusho Co., Ltd.); nonionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid esters (PLURONIC L10, L31, L61, L62, 10R5, 1782 and 25R2, TETRONIC 304, 701, 704, 901, 904 and 150R1, manufactured by BASF); and anionic surfactants such as W004, W005 and W017 (manufactured by Yusho Co., Ltd.), can also be used.

—Other Additives—

In addition to the additives described above, specific examples of additives include fillers such as glass and alumina; alkali-soluble resins such as an itaconic acid copolymer, a crotonic acid copolymer, a maleic acid copolymer, a partially esterified maleic acid copolymer, an acidic cellulose derivative, a compound obtained by adding an acid anhydride to a polymer having hydroxyl groups, an alcohol-soluble nylon, and a phenoxy resin formed from bisphenol A and epichlorohydrin; polymeric dispersants such as EFKA-46, EKFA-47, EFKA-47EA, EFKA POLYMER 100, EFKA POLYMER 400, EFKA POLYMER 401, and EFKA POLYMER 450 (all manufactured by Morishita Kagaku Sangyo Co., Ltd.), DISPERSE AID 6, DISPERSE AID 8, DISPERSE AID 15, and DISPERSE AID 9100 (manufactured by San Nopco, Ltd.); various SOLSPERSE dispersants such as SOLSPERSE 3000, 5000, 9000, 12000, 13240, 13940, 17000, 24000, 26000, and 28000 (all manufactured by Geneka Group); ADEKA PLURONIC L31, F38, L42, L44, L61, L64, F68, L72, P95, F77, P84, F87, P94, L101, P103, F108, L121, P-123 (all manufactured by Asahi Denka Kogyo K.K.), and ISONET S-20 (all manufactured by Sanyo Chemical Industries, Ltd.); ultraviolet absorbers such as 2-(3-t-butyl-5-methyl-2-hydroxyphenyl)-5-chlorobenzotriazole and alkoxybenzophenone; and aggregation preventing agents such as sodium polyacrylate.

Furthermore, in the case of promoting alkali-solubility of uncured portions, and attempting a further enhancement of developability of the colored photosensitive composition, it is preferable to add an organic carboxylic acid, preferably a low molecular weight organic carboxylic acid having a molecular weight of 1000 or less, to the colored photosensitive composition.

Specific examples of the organic carboxylic acid include aliphatic monocarboxylic acids such as formic acid, acetic acid, propionic acid, butyric acid, valeric acid, pivalic acid, caproic acid, diethylacetic acid, enanthic acid, and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, and citraconic acid; aliphatic tricarboxylic acids such as tricarballylic acid, aconitic acid, and camphoronic acid; aromatic monocarboxylic acids such as benzoic acid, toluic acid, cumic acid, hemellitic acid, and mesitylenic acid; aromatic polycarboxylic acids such as phthalic acid, isophthalic acid, terephthalic acid, trimellitic acid, trimesic acid, mellophanic acid, and pyromellitic acid; and phenylacetic acid, hydroatropic acid, hydrocinnamic acid, mandelic acid, phenylsuccinic acid, atropic acid, cinnamic acid, methyl cinnamate, benzyl cinnamate, cinnamylidene acetic acid, coumaric acid, and umbellic acid.

—Thermal Polymerization Inhibitor—

The colored photosensitive composition used in the invention may further include a thermal polymerization inhibitor, in addition to the components described above.

Examples of the thermal polymerization inhibitor that are useful include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and 2-mercaptobenzimidazole.

—Method for Preparing Colored Photosensitive Composition—

The colored composition of the invention is prepared by mixing the various components described above and optional components as necessary.

On the occasion of preparing the colored photosensitive composition, the various components that constitute the colored composition may be blended all at once, or the various components may be dissolved or dispersed in solvents, and then may be blended in sequence. Furthermore, the order of introduction or operating conditions at the time of blending is not particularly restricted. For example, a composition may be prepared by dissolving/dispersing all the components in a solvent at the same time, or if necessary, the various components may be appropriately prepared into two or more solutions/dispersion liquids, and a composition may be prepared by mixing these at the time of use (at the time of application).

However, when a pigment is used as a component, it is preferable to disperse the pigment in advance, and to prepare a colored composition from the pigment dispersion liquid.

When a colored composition is used for the preparation of the colored photosensitive composition used in the invention, the content of the colored composition is preferably such that the content of the coloring material is in the range of from 30% by mass to 70% by mass, the content of the coloring material is more preferably in the range of from 35% by mass to 60% by mass, and the content of the coloring material is still more preferably in the range of from 40% by mass to 60% by mass, with respect to the total solid content (mass) of the colored photosensitive composition.

When the content of the coloring material in the colored photosensitive composition is in this range, it is effective to secure excellent color characteristics with a sufficient color density.

The colored photosensitive composition prepared as described above may be filtered using a filter having a pore diameter of preferably from 0.01 μm to 3.0 μm, and more preferably from 0.05 μm to 0.5 μm, and then can be provided for use.

Since the colored photosensitive composition of the invention can form a colored cured film exhibiting high luminance and excellent hues and contrast, the colored photosensitive composition can be suitably used for forming colored pixels of color filters and the like that are used in liquid crystal display devices (LCD) or solid-state image sensors (for example, CCD and CMOS), and for producing printing inks, inkjet inks, coating materials, and the like.

<Color Filter and Method of Producing the Same>

The color filter of the invention is configured to include a substrate, and colored pixels formed from the colored photosensitive composition including a phthalocyanine compound (1), on the substrate. Colored regions on the substrate are constructed from colored films of red (R), green (G), blue (B) and the like, which constitute the various pixels of the color filter. Since the color filter of the invention is formed to contain a phthalocyanine compound (1), images exhibit high luminance and excellent hues and contrast, and thus the color filter is suitable particularly for liquid crystal display devices, organic EL display devices, and solid-state image sensors.

The color filter of the invention may be formed by any method, as long as the method can provide colored regions (colored pattern) obtained by curing the colored photosensitive composition of the invention.

The method of producing a color filter of the invention is configured to include Step (1) of applying the colored photosensitive composition described above on a support, and forming a colored layer (also referred to as colored composition layer); Exposure Step (2) of patternwise exposing the colored composition layer formed in Step (1) (preferably, through a mask), and thereby forming a latent image; and Step (3) of developing the colored layer in which the latent image is formed, and thereby forming colored regions (colored pattern).

Furthermore, in regard to the method of producing a color filter of the invention, an embodiment of further including, in particular, Step (4) of irradiating the colored pattern formed in Step (3) with ultraviolet radiation; and Step (5) of subjecting the colored pattern that has been irradiated with ultraviolet radiation in Step (3), to a heating treatment, is preferred.

A color filter can also be produced by methods such as the transfer method described in JP-A No. 2009-116078, and the inkjet method described in JP-A No. 2009-134263.

Hereinafter, the method of producing a color filter of the invention will be described more specifically.

—Step (1)—

In the method of producing a color filter of the invention, first, the colored photosensitive composition of the invention as described above is applied on a support by a coating method such as spin coating, flow cast coating, or roll coating, to form a colored composition layer, subsequently preliminary curing (prebake) is performed if necessary, and the colored composition layer is dried.

Examples of the support include substrates formed from soda glass, alkali-free glass, borosilicate glass, quartz glass and resins, which are used in liquid crystal display devices and the like; and photoelectric conversion element substrates and silicon substrates for CCD, CMOS, and organic CMOS that are used in solid-state image sensors.

Furthermore, these supports may also be provided with an undercoat layer, if necessary, in order to achieve amelioration of adhesion with upper layers, prevention of substance diffusion, or flattening of the surface.

The colored composition of the invention is applied on a substrate, directly or through another layer, by coating methods such as spin coating, slit coating, flow cast coating, roll coating, bar coating, and inkjetting, and thereby a coating film of the colored composition can be formed.

Regarding the conditions for prebake, conditions of heating using a hot plate or an oven at 70° C. to 130° C. for about 0.5 minutes to 15 minutes, may be used.

Furthermore, the thickness of the colored composition layer formed by the colored composition is appropriately selected according to the purpose. For a color filter for liquid crystal display devices, the thickness is preferably in the range of from 0.2 μm to 5.0 μm, more preferably in the range of from 1.0 μm to 4.0 μm, and most preferably in the range of from 1.5 μm to 3.5 μm. Furthermore, for a color filter for solid-state image sensors, the thickness is preferably in the range of from 0.2 μm to 5.0 μm, more preferably in the range of from 0.3 μm to 2.5 μm, and most preferably in the range of from 0.3 μm to 1.5 μm.

The thickness of the colored composition layer is the film thickness obtainable after the prebake.

—Step (2)—

Subsequently, in the method of producing a color filter of the invention, the colored composition layer formed on a support is subjected to exposure, for example, through a photomask. The light or radiation that can be applied to exposure is preferably g-line, h-line, i-line, KrF light, or ArF light, and i-line is particularly preferred. When the i-line is used as the light to be irradiated, it is preferable to irradiate the radiation in an amount of exposure of from 100 mJ/cm² to 10,000 mJ/cm².

Furthermore, as other exposure light, various mercury lamps such as an ultrahigh pressure mercury lamp, a high pressure mercury lamp, a medium pressure mercury lamp, and a low pressure mercury lamp; a chemical lamp, a carbon arc lamp, a xenon lamp, a metal halide lamp, various laser light sources of visible light and ultraviolet radiation, a fluorescent lamp, a tungsten lamp, solar light and the like can also be used.

—Exposure Step Using Laser Light Source—

In the exposure system using a laser light source, an ultraviolet light laser is used as the light source.

The light to be irradiated is preferably ultraviolet laser light having a wavelength in the range of from 300 nm to 380 nm, and more preferably, ultraviolet laser light having a wavelength in the range of from 300 nm to 360 nm is preferable from the viewpoint that the wavelength of the ultraviolet laser light coincides with the photosensitive wavelength of the resist. Specifically, the third harmonic wave (355 nm) of a Nd:YAG laser, which is a relatively inexpensive solid laser having a high output power, or XeCl (308 nm) or XeF (353 nm) of an excimer laser can be suitably used.

The amount of exposure of the object to be exposed (pattern) is in the range of from 1 mJ/cm² to 100 mJ/cm², and more preferably in the range of from 1 mJ/cm² to 50 mJ/cm². When the amount of exposure is in this range, it is preferable from the viewpoint of the productivity of pattern formation.

There are no particular limitations on the exposure apparatus, but commercially available products such as CALLISTO (manufactured by V Technology Co., Ltd.), EGIS (manufactured by V Technology Co., Ltd.), and DF2200G (manufactured by Dainippon Screen Manufacturing Co., Ltd.) can be used. Furthermore, apparatuses other than those described above are also suitably used.

The colored composition layer exposed as described above can be heated.

Furthermore, exposure can be carried out while allowing nitrogen gas to flow into the chamber, in order to suppress oxidative discoloration of the coloring material in the colored composition layer.

—Step (3)—

Subsequently, the colored composition layer after exposure is subjected to development with a developer liquid. Thereby, a colored pattern (resist pattern) can be formed.

Regarding the developer liquid, a combination of various organic solvents, or an alkaline aqueous solution can be used, as long as the liquid dissolves uncured areas (unexposed areas) of the colored composition layer, and does not dissolve cured areas (exposed areas). When the developer liquid is an alkaline aqueous solution, it is desirable to adjust the alkali concentration preferably to pH 11 to pH 13, and more preferably to pH 11.5 to pH 12.5. Examples of the alkaline aqueous solution include alkaline aqueous solutions of sodium hydroxide, potassium hydroxide, sodium carbonate, sodium hydrogen carbonate, sodium silicate, sodium metasilicate, aqueous ammonia, ethylamine, diethylamine, dimethylethanolamine, tetramethylammonium hydroxide, tetraethylammonium hydroxide, choline, pyrrole, piperidine, and 1,8-diazabicyclo[5,4,0]-7-undecene.

The development time is preferably from 30 seconds to 300 seconds, and more preferably from 30 seconds to 120 seconds. The development temperature is preferably from 20° C. to 40° C., and more preferably 23° C.

Development can be carried out in a paddle mode, a shower mode, a spray mode or the like.

After development is performed using an alkaline aqueous solution, it is preferable to wash with water.

Thereafter, in the method of producing a color filter of the invention, the colored pattern formed by development can be subjected to post-heating and/or post-exposure as necessary, and thereby curing of the colored pattern can be accelerated.

—Step (4)—

In the method of producing a color filter of the invention, particularly, the colored pattern (pixels) formed using the colored composition can be subjected to post-exposure by ultraviolet irradiation.

—Step (5)—

It is preferable to further carry out a heating treatment on the colored pattern that has been subjected to post-exposure by ultraviolet irradiation as described above. When the colored pattern thus formed is subjected to a heating treatment (so-called postbake treatment), the colored pattern can be further cured. This heating treatment can be carried out using, for example, a hot plate, various heaters, and ovens.

The temperature at the time of the heating treatment is preferably from 100° C. to 300° C., and more preferably from 150° C. to 250° C. Furthermore, the heating time is preferably about from 10 minutes to 120 minutes.

The colored pattern obtained in this manner constitutes pixels in the color filter. In regard to the production of a color filter having pixels of plural hues, Step (1), Step (2), Step (3), and if necessary, Step (4) or Step (5) described above may be repeated in accordance with the desired number of colors.

Meanwhile, the Step (4) and/or Step (5) may be carried out every time the formation, exposure and development of a colored composition layer of a single color are completed (for every single color), or the Step (4) and/or Step (5) may be carried out collectively after the formation, exposure and development of all the colored composition layers of the desired number of colors are completed.

A color filter obtained by the method of producing a color filter of the invention (color filter of the invention) has high luminance, and has excellent hues and contrast, since the colored photosensitive composition of the invention is used.

The color filter of the invention can be used in a liquid crystal display device or a solid-state image sensor, and is particularly suitable for the applications of liquid crystal display devices. When the color filter is used in a liquid crystal display device, display of images having high luminance and excellent contrast is enabled, while favorable hues are attained.

<Liquid Crystal Display Device and Organic EL Display Device>

The liquid crystal display device and organic EL display device of the invention include the color filter of the invention described above.

The definitions of the liquid crystal display device and organic EL display device, or the details of the various display devices are described in, for example, “Electronic Display Devices (written by SASAKI, Akio, published by Kogyo Chosakai Publishing Co., Ltd. in 1990)”, “Display Devices (written by IBUKI, Sumiaki, published by Sangyo Tosho Publishing Co., Ltd. in 1989)”, and the like. Furthermore, the details of the liquid crystal display devices are described in, for example, “Jisedai Ekisho Disupurei Gijutsu (Next-generation Liquid Crystal Display Technology) (edited by UCHIDA, Tatsuo, published by Kogyo Chosakai Publishing Co., Ltd. in 1994)”. There are no particular limitations on the liquid crystal display devices to which the invention is applicable, and the invention can be applied to, for example, the liquid crystal display devices of various modes described in the “Jisedai Ekisho Disupurei Gijutsu” described above.

The color filter of the invention is effective, among others, in liquid crystal display devices of a color TFT system in particular. The details of the liquid crystal display devices of a color TFT system are described in, for example, “Color TFT Liquid Crystal Display (published by Kyoritsu Shuppan Co., Ltd. in 1996)”. Furthermore, the invention can also be applied to liquid crystal display devices with extended viewing angles, such as a horizontal electric field driving system such as IPS, and a pixel division system such as MVA, or to STN, TN, VA, OCS, FFS, R-OCB, and the like.

Furthermore, the color filter of the invention can also be provided for a bright, high precision COA (Color-filter On Array) system.

When the color filter of the invention is used in a liquid crystal display device, high contrast can be realized when combined with a three-wavelength tube of a conventionally known cold cathode tube, and when LED light sources of red, green and blue (RGB-LED) are used as back lights, a liquid crystal display device having high luminance, high color purity, and favorable color reproducibility can be provided.

Furthermore, the color filter of the invention can be used in solid-state image sensors such as CCD and CMOS, and when the color filter is used in a solid-state image sensor, a color filter having high luminance and favorable color separability can be provided.

### EXAMPLES

Hereinafter, the invention will be described more specifically by way of Examples, but the invention is not intended to be limited to the following Examples as long as the gist is maintained. Unless particularly stated otherwise, the unit “parts” is on a mass basis.

### Synthesis Example 1

### Synthesis of Phthalonitrile Compound

[α-{(4-COOC₂H₄OCH₃)C₆H₄O}ₐ, β-{(4-COOC₂H₄OCH₃)C₆H₄O}₁₋ₐCl₃ phthalonitrile] (0≦a<1) (Intermediate 1)

In a 150-ml flask, 7.98 g (0.030 moles) of tetrachlorophthalonitrile (hereinafter, abbreviated to TCPN), 5.95 g (0.030 moles) of p-hydroxybenzoic acid methyl cellosolve, and 31.91 g of acetonitrile were introduced, and the contents were stirred for about 30 minutes using a magnetic stirrer until the internal temperature became steady at 40° C. Subsequently, 4.56 g (0.033 moles) of potassium carbonate was introduced therein, and the mixture was allowed to react for about 3 hours. After cooling, a solution obtained by suction filtration was subjected to an evaporation treatment under the conditions of about 110° C. x 1 hour to distill off the solvent. Then, the residue was dried in a vacuum overnight at about 110° C., and thus about 13.1 g of an intermediate 1 (yield with respect to TCPN: 102.4 mol %) was obtained.

### Synthesis Example 2

### Synthesis of Phthalocyanine Compound (Hereinafter, Abbreviated to Pc-1)

[ZnPc-{α-(4-COOC₂H₄OCH₃)C₆H₄O}ₓ, {β-(4-COOC₂H₄OCH₃)C₆H₄O}_{3.8-x}H_{0.8}Cl_{11.4}] (0≦x<3.8)

In a 150-ml flask, 10.21 g (0.024 moles) of the intermediate 1 obtained in Synthesis Example 1, 0.16 g (0.001 moles) of phthalonitrile, and 3.46 g of benzonitrile (BN) were introduced, and under a nitrogen gas stream (10 ml/min), the contents were stirred for about 1 hour using a magnetic stirrer until the internal temperature became steady at 160° C. Subsequently, 2.22 g (0.007 moles) of zinc iodide was introduced therein, and the mixture was allowed to react for about 12 hours. After cooling, the reaction solution was subjected to an evaporation treatment under the conditions of 140° C.×1 hr to distill off the solvent. Subsequently, to the solid thus obtained, methyl cellosolve (6.9 g) in an amount corresponding to the weight obtained by subtracting the weight of BN (3.46 g) from the sum of the weights (10.37 g) of the intermediate 1 and phthalonitrile used in the phthalocyanization reaction, was added, and the mixture was dissolved while stirred. Thus, a crystallization solution was prepared. Next, the crystallization solution thus prepared was added dropwise to methanol (103.8 g) in an amount corresponding to 10 times the sum of the weights of the intermediate 1 and phthalonitrile used in the phthalocyanization reaction, and the mixture was stirred for 30 minutes. Thereafter, distilled water (72.6 g) in an amount corresponding to seven times the sum of the weight of the intermediate, was added dropwise thereto over 30 minutes, and after completion of the dropwise addition, the mixture was stirred for another 30 minutes to precipitate crystals. The crystals thus obtained were filtered by suction, and then methanol (51.9 g) in an amount corresponding to ½ times the amount at the time of crystallization was added again thereto, followed by stirring for 30 minutes. Subsequently, distilled water (36.3 g) in an amount corresponding to ½ times the amount at the time of crystallization was added dropwise thereto over 30 minutes, and after completion of the dropwise addition, the mixture was stirred for another 30 minutes, to thereby perform washing and purification. After suction filtering, crystals thus taken out were dried in a vacuum overnight at about 60° C., and thus about 10.7 g of Pc-1 (yield with respect to the intermediate 1 and phthalonitrile: 99.2 mol %) was obtained.

<Preparation of Pigment Dispersion Composition YG-1>

Components of the following composition were mixed, and the mixture was mixed with stirring using a homogenizer at a speed of rotation of 3,000 rpm for 3 hours. Thus, a mixed solution containing a pigment was prepared.

[Composition]

| | |
|---|---|
| Pigment Yellow 138 | 130 parts |
| Propylene glycol monomethyl ether acetate solution | 15 parts |
| (solid content: 50%) of benzyl methacrylate/methacrylic | |
| acid (=70/30 [molar ratio]) copolymer (Mw: 5,000) | |
| Dispersant (DISPERBYK-161, manufactured by BYK | 60 parts |
| Chemie Japan, Ltd.) | |
| Propylene glycol monomethyl ether acetate | 795 parts |

Subsequently, the mixed solution obtained as described above was further subjected to a dispersion treatment for 12 hours with a bead dispersing machine, DISPERMAT (manufactured by VMA-Getzmann GmbH) using 0.3-mmφ zirconia beads, and then was further subjected to a dispersion treatment using a high pressure dispersing machine attached with a pressure reducing mechanism, NANO-3000-10 (manufactured by Nippon BEE Chemical Co., Ltd.), at a pressure of 2000 kg/cm³ at a flow rate of 500 g/min. This dispersion treatment was repeated 10 times, and thus, a pigment dispersion composition YG-1 was obtained.

<Preparation of Pigment Dispersion Compositions YG-2, CG-1, CG-2, and CG-3>

Here, pigment dispersion compositions YG-2, YG-3, CG-1, CG-2 and CG-3 were prepared in the same manner as in the preparation of YG-1, except that the “Pigment Yellow 138” used in the preparation of the pigment dispersion composition YG-1 was respectively changed to “Pigment Yellow 150” (YG-2), “Pigment Green 7” (CG-1), “Pigment Green 36” (CG-2), and “Pigment Green 58” (CG-3).

A dye compound represented by the following structural formula is shown below as a yellow coloring material, in addition to known pigments.

(D−1): Propylene glycol monomethyl ether acetate solution (solid content: 13%) of dye compound represented by the following structural formula:

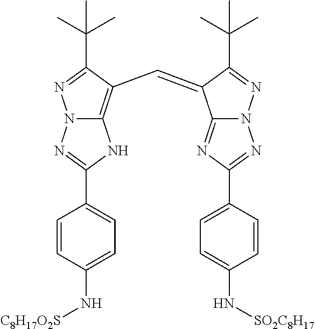

(D-2): Propylene glycol monomethyl ether acetate solution (solid content: 13%) of dye compound represented by the following structural formula:

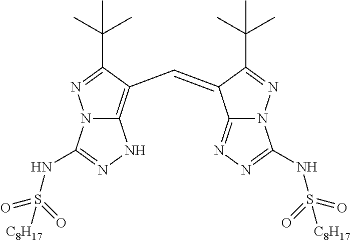

(D-3): Propylene glycol monomethyl ether acetate solution (solid content: 13%) of dye compound represented by the following structural formula:

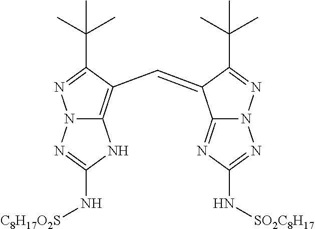

(D-4): Propylene glycol monomethyl ether acetate solution (solid content: 13%) of dye compound represented by the following structural formula:

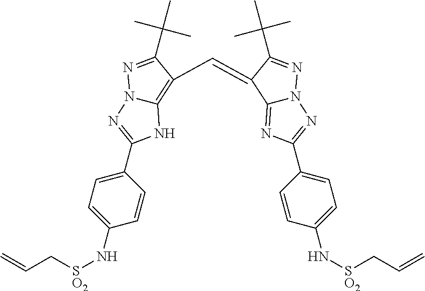 [SMILES: C=CCS(=O)(=O)Nc1ccc(-c2nc3/c(=C\c4c(C(C)(C)C)nn5nc(-c6ccc(NS(=O)(=O)CC=C)cc6)[nH]c45)c(C(C)(C)C)nn3n2)cc1]

(D-5): Propylene glycol monomethyl ether acetate solution (solid content: 13%) of the azo dye described in Examples [Synthesis Example of azo dye (3)] of JP-A No. 2011-197669

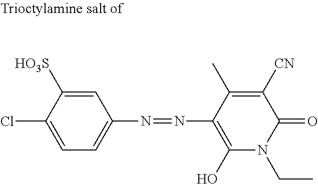 [SMILES: CCn1c(O)c(N=Nc2ccc(Cl)c(S(=O)(=O)O)c2)c(C)c(C#N)c1=O]

Preparation of Colored Photosensitive Composition

### Example 1

| | | |
|---|---|---|
| Phthalocyanine compound Pc-1 | 10 | parts |
| Yellow coloring material YG-1 | 30 | parts |
| Propylene glycol monomethyl ether acetate solution | 12 | parts |
| (solid content: 50%) of benzyl methacrylate/methacrylic | | |
| acid (=70/30 [molar ratio]) copolymer (Mw: 30,000) | | |
| DPHA (manufactured by Nippon Kayaku Co., Ltd.) | 12 | parts |
| 2-(o-chlorophenyl)-4,5-diphenylimidazolyl dimer | 3 | parts |
| (photopolymerization initiator) | | |
| 2-Mercaptobenzothiazole (hydrogen donating compound) | 2 | parts |
| Polymerization inhibitor: p-methoxyphenol | 0.001 | parts |
| Fluorine-containing surfactant (trade name: MEGAFACE | 0.5 | parts |
| F475, manufactured by DIC Corp.) | | |
| Propylene glycol monomethyl ether acetate | 129 | parts |

### Example 2 to Example 11

Compositions were prepared in the same manner as in Example 1, except that the various components described in Example 1 were changed to the various components described in Table 1.

(C-1): 2-(o-chlorophenyl)-4,5-diphenylimidazolyl dimer

(C-2): 1-(0-acetyloxime)-1-[9-ethyl-6-(thiophenoyl)-9H-carbazol-3-yl]propanone (C-3):

4-[o-bromo-p-N,N-di(ethoxycarbonyl)aminophenyl]-2,6-di(trichloromethyl)-s-triazine

(B-1): Benzyl methacrylate/methacrylic acid (=70/30 [molar ratio])

(B-2): Allyl methacrylate/methacrylic acid (=70/30 [molar ratio])

### Example 12 to Example 17

Compositions were prepared in the same manner as in Example 1, except that the amount of the phthalocyanine compound of Example 1 was changed to 5 parts, 40 parts of a green pigment dispersion liquid was added, and the various components were changed to the various components indicated in Table 1.

### Example 18 to Example 19

Compositions were prepared in the same manner as in Example 12, except that the amount of the yellow coloring material D-1 of Example 12 was changed to 15 parts, 15 parts of a yellow pigment dispersion liquid was added, and the various components were changed to the various components indicated in Table 1.

### Comparative Example 1 to Comparative Example 4

Compositions were prepared in the same manner as in Example 1, except that the phthalocyanine compound of Example 1 was changed to 60 parts of a green pigment dispersion liquid, and the various components were changed to the various components indicated in Table 1.

—Evaluation—

The various colored photosensitive compositions obtained as described above were evaluated for transmittance, heat resistance, and contrast, by the methods described below.

For each of the colored photosensitive compositions prepared in Examples and Comparative Examples, the colored photosensitive composition obtained as described above was applied on a glass plate (#1737; manufactured by Corning, Inc.) by a spin coating method, subsequently volatile components were volatilized at 100° C. for 3 minutes, and thus a colored film was formed. After cooling, this colored film was exposed using an ultrahigh pressure mercury lamp. The amount of irradiated light was set to 100 mJ/cm². Next, postbake was performed at 230° C. for 20 minutes, and thus a glass substrate with a colored layer having a film thickness of 2 μm was obtained.

(Transmittance)

The transmittance of the glass substrate having a colored layer thus obtained was measured using a microscopic spectroscopic analyzer, OSP-SP200, manufactured by Olympus Corp., and a comparison based on the transmittances at 500 nm was made. A higher transmittance value indicates higher luminance and favorable performance. Evaluation was made according to the following evaluation criteria.

<Evaluation Criteria>

A: Transmittance of 90% or higher

B: Transmittance of 85% or more but less than 90%

C: Transmittance of less than 85%

(Heat Resistance)

The glass substrate having a colored layer thus obtained was further heated at 230° C. for 40 minutes, and the transmittance after heating was measured using a microscopic spectroscopic analyzer, OSP-SP200, manufactured by Olympus Corp., and the color difference before and after heating (ΔE*ab) was determined. A smaller color difference value indicates a smaller change and favorable performance. Evaluation was made according to the following evaluation criteria.

<Evaluation Criteria>

A: Color difference of less than 3

B: Color difference of 3 or more but less than 5

C: Color difference of 5 or more

(Contrast)

The glass substrate having a colored layer thus obtained was interposed between polarizing plates, and the luminance when the polarizing plates were parallel to each other, and the luminance when the polarizing plates were perpendicular to each other were measured using a BM-5 manufactured by Topcon Corp. The value obtainable by dividing the luminance at the time of being parallel, by the luminance at the time of being perpendicular (=luminance at the time of being parallel/luminance at the time of being perpendicular) was used as an index for evaluating the contrast. When the value described above was 20,000 or more, the contrast was designated as A, and when the value was less than 20,000, the contrast was designated as B.

TABLE 1

| | Phthalocyanine | Green pigment | Yellow coloring | Polymerization | | | | |
|---|---|---|---|---|---|---|---|---|
| | compound | dispersion | material | initiator | Copolymer | Transmittance | Heat resistance | Contrast |
| Example 1 | Pc-1 | — | YG-1 | C-1 | B-1 | A | A | A |
| Example 2 | Pc-1 | — | D-1 | C-2 | B-1 | A | B | A |
| Example 3 | Pc-1 | — | D-1 | C-1 | B-2 | A | A | A |
| Example 4 | Pc-1 | — | D-2 | C-1 | B-2 | A | A | A |
| Example 5 | Pc-1 | — | D-3 | C-1 | B-2 | A | A | A |
| Example 6 | Pc-1 | — | D-4 | C-1 | B-2 | A | A | A |
| Example 7 | Pc-1 | — | D-5 | C-1 | B-2 | B | B | A |
| Example 8 | Pc-1 | — | D-1 | C-1 | B-1 | A | B | A |
| Example 9 | Pc-1 | — | YG-1 | C-2 | B-1 | A | A | A |
| Example 10 | Pc-1 | — | YG-2 | C-1 | B-1 | A | A | A |
| Example 11 | Pc-1 | — | YG-1 | C-3 | B-1 | B | A | A |
| Example 12 | Pc-1 | CG-3 | D-1 | C-1 | B-2 | B | A | A |
| Example 13 | Pc-1 | CG-3 | D-2 | C-1 | B-2 | B | A | A |
| Example 14 | Pc-1 | CG-3 | D-3 | C-1 | B-2 | B | A | A |
| Example 15 | Pc-1 | CG-3 | D-4 | C-2 | B-2 | B | A | A |
| Example 16 | Pc-1 | CG-1 | YG-1 | C-1 | B-1 | B | A | A |
| Example 17 | Pc-1 | CG-2 | YG-1 | C-1 | B-1 | B | A | A |
| Example 18 | Pc-1 | CG-3 | YG-1/D-1 | C-1 | B-2 | B | A | A |
| Example 19 | Pc-1 | CG-3 | YG-2/D-1 | C-1 | B-2 | B | A | A |
| Comparative | — | CG-3 | YG-1 | C-1 | B-1 | C | A | B |
| Example 1 | | | | | | | | |
| Comparative | — | CG-3 | YG-2 | C-2 | B-1 | C | A | B |
| Example 2 | | | | | | | | |
| Comparative | — | CG-1 | YG-1 | C-1 | B-1 | C | A | B |
| Example 3 | | | | | | | | |
| Comparative | — | CG-2 | YG-1 | C-1 | B-1 | C | A | B |
| Example 4 | | | | | | | | |

From the results shown in Table 1, it is understood that a colored cured film obtained using the colored composition related to the invention has excellent transmittance, heat resistance, and contrast. Particularly, it is understood that a colored composition including at least one selected from YG-1, YG-2 and Dl to D4 as a yellow coloring material is especially superior.

The disclosure of Japanese Patent Application No. 2012-051017, filed Mar. 7, 2012, is incorporated herein by reference in its entirety. All publications, patent applications, and technical standards mentioned in this specification are herein incorporated by reference to the same extent as if each individual publication, patent application, or technical standard was specifically and individually indicated to be incorporated by reference.

The foregoing description of the embodiments of the invention has been provided for the purpose of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention in various embodiments and with the various modifications as are suited to the particular use contemplated. It is intended that the scope of the invention be defined by the following claims and their equivalents.

What is claimed is:

1. A colored composition, comprising: (A) a compound represented by the following Formula (1); (B) a yellow coloring material; and (C) a solvent: 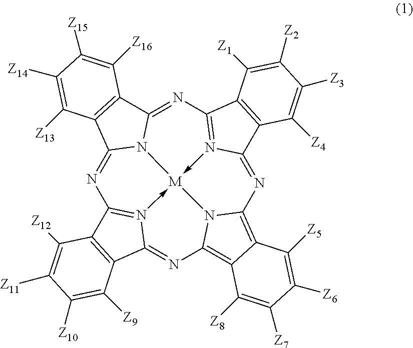
wherein, in Formula (1), each of Z₁ to Z₁₆ independently represents a hydrogen atom, a halogen atom, a group represented by the following Chemical Formula (2), a group represented by the following Chemical Formula (3), or a group represented by the following Chemical Formula (2′); from one to eight of Z₁ to Z₁₆ each independently represent a group represented by the following Chemical Formula (2) or a group represented by the following Chemical Formula (2′); at least one of the from one to eight of Z₁ to Z₁₆ represents a group represented by the following Chemical Formula (2); and M represents two hydrogen atoms, a metal atom, a metal oxide, or a metal halide:
—X-A₁ Chemical Formula (2):
wherein, in Chemical Formula (2), X represents an oxygen atom or a sulfur atom; A₁ represents a phenyl group, a phenyl group having one to five substituents R, or a naphthyl group having one to seven substituents R; each of the substituents R independently represents a nitro group, COOR₁, OR₂, a halogen atom, an aryl group, a cyano group, or an alkyl group that has 1 to 8 carbon atoms and that may be substituted with a halogen atom; R₁ represents an alkyl group having 1 to 8 carbon atoms; the alkyl group having 1 to 8 carbon atoms represented by R₁ may be substituted with an alkyloxy group having 1 to 8 carbon atoms, a halogen atom, or an aryl group; and R₂ represents an alkyl group having 1 to 8 carbon atoms:
R₃—OₙR₄ Chemical Formula (3):
wherein, in Chemical Formula (3), R₃ represents an alkylene group having 1 to 3 carbon atoms; R₄ represents an alkyl group having 1 to 8 carbon atoms; and n represents an integer from 1 to 4:
—OR′—OₗR″ Chemical Formula (2′):
wherein, in Chemical Formula (2′), R′ represents an alkylene group having 1 to 3 carbon atoms; R″ represents an alkyl group having 1 to 8 carbon atoms; and 1 represents an integer from 0 to 4; and
wherein (B) the yellow coloring material includes at least one selected from the group consisting of Pigment Yellow 138, Pigment Yellow 150, a compound represented by the following Formula (6), and a compound represented by the following Formula (7): 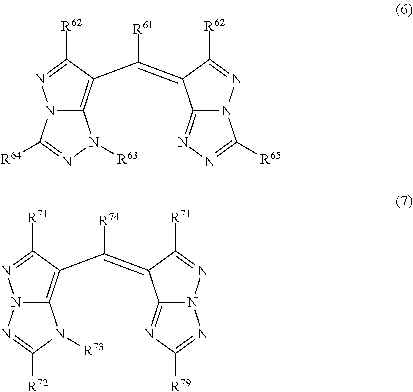
wherein, in Formula (6) and Formula (7), each of R⁶¹ to R⁶⁵, R⁷¹ to R⁷⁴, and R⁷⁹ independently represents a hydrogen atom, an alkyl group, an alkoxy group, an alkoxycarbonyl group, a carbamoyl group, a sulfamoyl group, a cyano group, an aryl group, or a heteroaryl group.

2. The colored composition according to claim 1, wherein, in Formula (1), M represents at least one selected from the group consisting of a copper atom, a zinc atom, a cobalt atom, a nickel atom, an iron atom, vanadyl, titanyl, indium chloride, and tin(II) chloride.

3. The colored composition according to claim 1, wherein, in Formula (1), from one to eight of Z₁ to Z₁₆ each independently represent a group represented by Chemical Formula (2) or a group represented by Chemical Formula (2′), and at least one of the from one to eight of Z₁ to Z₁₆ represents a group represented by Chemical Formula (2), while the remainder of Z₁ to Z₁₆ each independently represent a hydrogen atom or a chlorine atom.

4. The colored composition according to claim 1, wherein, in Formula (1), any one or more of Z₁ to Z₁₆ represents a fluorine atom, a chlorine atom, a bromine atom, or an iodine atom.

5. The colored composition according to claim 1, wherein, in Chemical Formula (2), X represents an oxygen atom.

6. The colored composition according to claim 1, wherein (C) the solvent is an organic acid ester.

7. The colored composition according to claim 1, further comprising at least one green pigment selected from the group consisting of Pigment Green 7, Pigment Green 36, and Pigment Green 58.

8. A colored photosensitive composition, comprising: the colored composition according to claim 1; (D) a polymerizable compound; (E) a photopolymerization initiator; and (F) an alkali-soluble binder.

9. The colored photosensitive composition according to claim 8, wherein, in Formula (1), M represents at least one selected from the group consisting of a copper atom, a zinc atom, a cobalt atom, a nickel atom, an iron atom, vanadyl, titanyl, indium chloride, and tin(II) chloride.

10. The colored photosensitive composition according to claim 8, wherein, in Formula (1), from one to eight of Z₁ to Z₁₆ each independently represent a group represented by Chemical Formula (2) or a group represented by Chemical Formula (2′), and at least one of the from one to eight of Z₁ to Z₁₆ represents a group represented by Chemical Formula (2), while the remainder of Z₁ to Z₁₆ each independently represent a hydrogen atom or a chlorine atom.

11. The colored photosensitive composition according to claim 8, wherein, in Formula (1), any one or more of Z₁ to Z₁₆ represents a fluorine atom, a chlorine atom, a bromine atom, or an iodine atom.

12. The colored photosensitive composition according to claim 8, wherein, in Chemical Formula (2), X represents an oxygen atom.

13. The colored photosensitive composition according to claim 8, further comprising at least one green pigment selected from the group consisting of Pigment Green 7, Pigment Green 36, and Pigment Green 58.

14. The colored photosensitive composition according to claim 8, wherein (E) the photopolymerization initiator includes at least one selected from the group consisting of a compound containing an oxime ester, and a hexaarylbisimidazole compound.

15. The colored photosensitive composition according to claim 8, wherein (F) the alkali-soluble binder has an ethylenically unsaturated group as a substituent.

16. The colored photosensitive composition according to claim 8, wherein (C) the solvent is an organic acid ester.

17. A color filter, comprising a colored layer formed using the colored photosensitive composition according to claim 8.

18. A liquid crystal display device, comprising the color filter according to claim 17.

19. An organic EL display device, comprising the color filter according to claim 17.

20. A solid-state image sensor, comprising the color filter according to claim 17.
